(19) United States
(12) Patent Application Publication
(10) Pub. No.: US 2026/0052888 A1
(43) Pub. Date: Feb. 19, 2026

(54) SEMICONDUCTOR DEVICE AND METHOD OF MAKING

(71) Applicant: Taiwan Semiconductor Manufacturing Company Limited, Hsin-Chu (TW)

(72) Inventors: Jheng-Hong Jiang, Hsinchu (TW); Shing-Huang Wu, Hsin-Chu (TW)

(21) Appl. No.: 18/804,320

(22) Filed: Aug. 14, 2024

(51) Int. Cl. H10K 59/80; H10K 59/12; H10K 59/122; H10K 59/131; H10K 59/38; H10K 71/20

(52) U.S. Cl. CPC H10K 59/878; H10K 59/1201; H10K 59/122; H10K 59/131; H10K 59/38; H10K 71/233

(57) ABSTRACT

A semiconductor device is provided. The semiconductor device includes a first organic light-emitting diode (OLED) cell and a second OLED cell. The first OLED cell includes a first reflective base, a first electroluminescence structure over the first reflective base, and a first optical resonation structure between the first electroluminescence structure and the first reflective base. The second OLED cell includes a second reflective base, a second electroluminescence structure over the second reflective base, and a second optical resonation structure between the second electroluminescence structure and the second reflective base, wherein an elevation of the first reflective base is different than an elevation of the second reflective base.

### BACKGROUND

Semiconductor devices are used in a multitude of electronic devices, such as mobile phones, laptops, desktops, tablets, watches, gaming systems, and various other industrial, commercial, and consumer electronics. Semiconductor devices generally comprise semiconductor portions and wiring portions formed inside the semiconductor portions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a semiconductor device at a stage of fabrication, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9 illustrates a cross-sectional view of a semiconductor device at a stage of fabrication, in accordance with some embodiments.

FIG. 10 illustrates a cross-sectional view of a semiconductor device at a stage of fabrication, in accordance with some embodiments.

FIG. 11 illustrates a cross-sectional view of a semiconductor device at a stage of fabrication, in accordance with some embodiments.

FIG. 12 illustrates a cross-sectional view of a semiconductor device at a stage of fabrication, in accordance with some embodiments.

FIG. 13 illustrates a cross-sectional view of a semiconductor device at a stage of fabrication, in accordance with some embodiments.

FIG. 14 illustrates a cross-sectional view of a semiconductor device at a stage of fabrication, in accordance with some embodiments.

FIG. 15 illustrates a cross-sectional view of a semiconductor device at a stage of fabrication, in accordance with some embodiments.

FIG. 16 illustrates a cross-sectional view of a semiconductor device at a stage of fabrication, in accordance with some embodiments.

FIG. 17 illustrates a cross-sectional view of a semiconductor device at a stage of fabrication, in accordance with some embodiments.

FIG. 18 illustrates a cross-sectional view of a semiconductor device at a stage of fabrication, in accordance with some embodiments.

FIG. 19 illustrates a cross-sectional view of a semiconductor device at a stage of fabrication, in accordance with some embodiments.

FIG. 20 illustrates a cross-sectional view of a semiconductor device at a stage of fabrication, in accordance with some embodiments.

FIG. 21 illustrates a cross-sectional view of a semiconductor device at a stage of fabrication, in accordance with some embodiments.

FIG. 22 illustrates a cross-sectional view of a semiconductor device at a stage of fabrication, in accordance with some embodiments.

FIG. 23 illustrates a cross-sectional view of a semiconductor device at a stage of fabrication, in accordance with some embodiments.

FIG. 24A illustrates a cross-sectional view of a semiconductor device at a stage of fabrication, in accordance with some embodiments.

FIG. 24B illustrates a top view of a semiconductor device at a stage of fabrication, in accordance with some embodiments.

FIG. 24C illustrates a top view of a semiconductor device at a stage of fabrication, in accordance with some embodiments.

FIG. 24D illustrates a top view of a semiconductor device at a stage of fabrication, in accordance with some embodiments.

FIG. 25A illustrates a cross-sectional view of a semiconductor device at a stage of fabrication, in accordance with some embodiments.

FIG. 25B illustrates a top view of a semiconductor device at a stage of fabrication, in accordance with some embodiments.

FIG. 25C illustrates a top view of a semiconductor device at a stage of fabrication, in accordance with some embodiments.

FIG. 25D illustrates a top view of a semiconductor device at a stage of fabrication, in accordance with some embodiments.

FIG. 26 illustrates a cross-sectional view of a semiconductor device at a stage of fabrication, in accordance with some embodiments.

FIG. 27 illustrates a cross-sectional view of a semiconductor device, in accordance with some embodiments.

### DETAILED DESCRIPTION

The following disclosure provides several different embodiments, or examples, for implementing different features of the provided subject matter.

Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A semiconductor device has a first organic light-emitting diode (OLED) cell and a second OLED cell. The first OLED cell includes a first reflective base, a first electroluminescence structure over the first reflective base, and a first optical resonation structure between the first electroluminescence structure and the first reflective base. The second OLED cell includes a second reflective base, a second electroluminescence structure over the second reflective base, and a second optical resonation structure between the second electroluminescence structure and the second reflective base. In some embodiments, the first OLED cell is configured to emit light having a first color and the second OLED is configured to emit light having a second color different than the first color. In some embodiments, an elevation of the first reflective base is different than an elevation of the second reflective base. In some embodiments, the first electroluminescence structure and the second electroluminescence structure are coplanar.

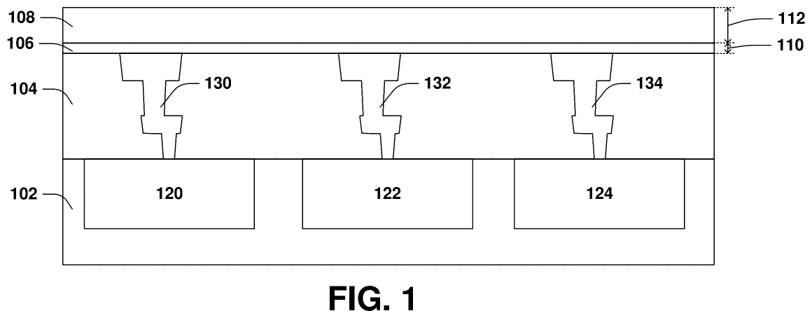

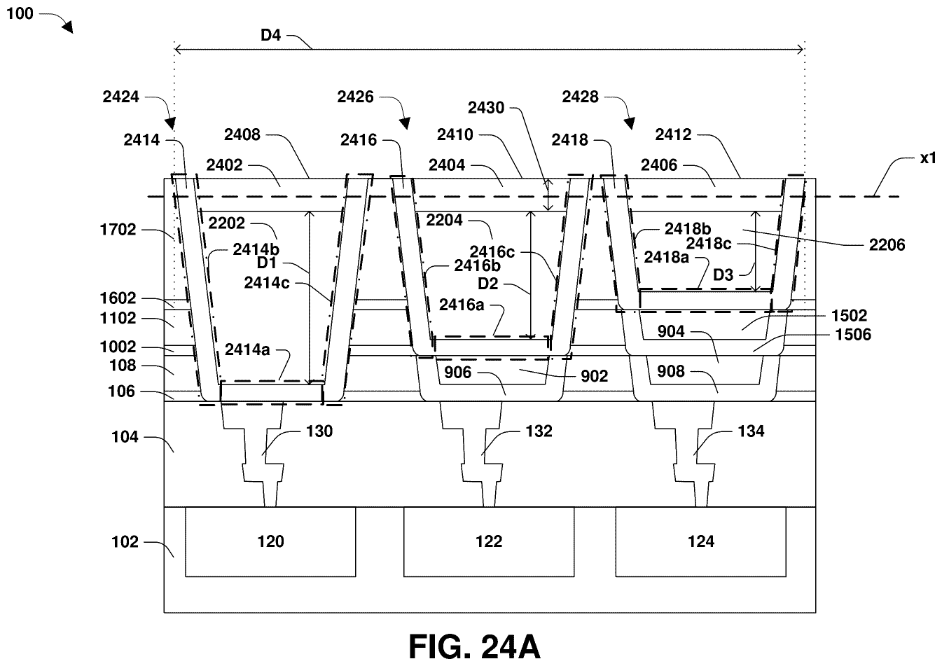

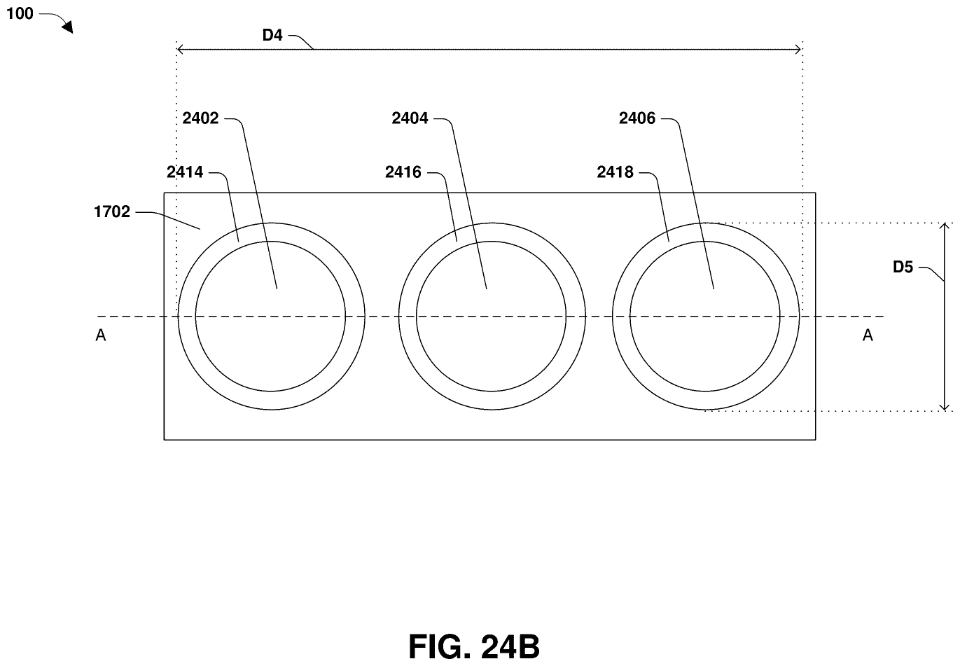

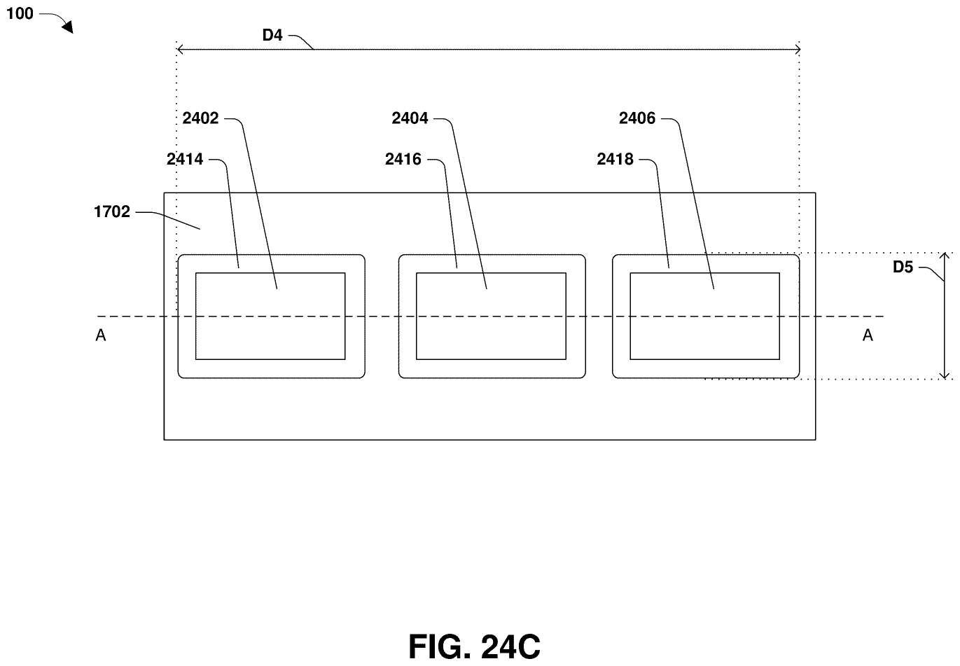

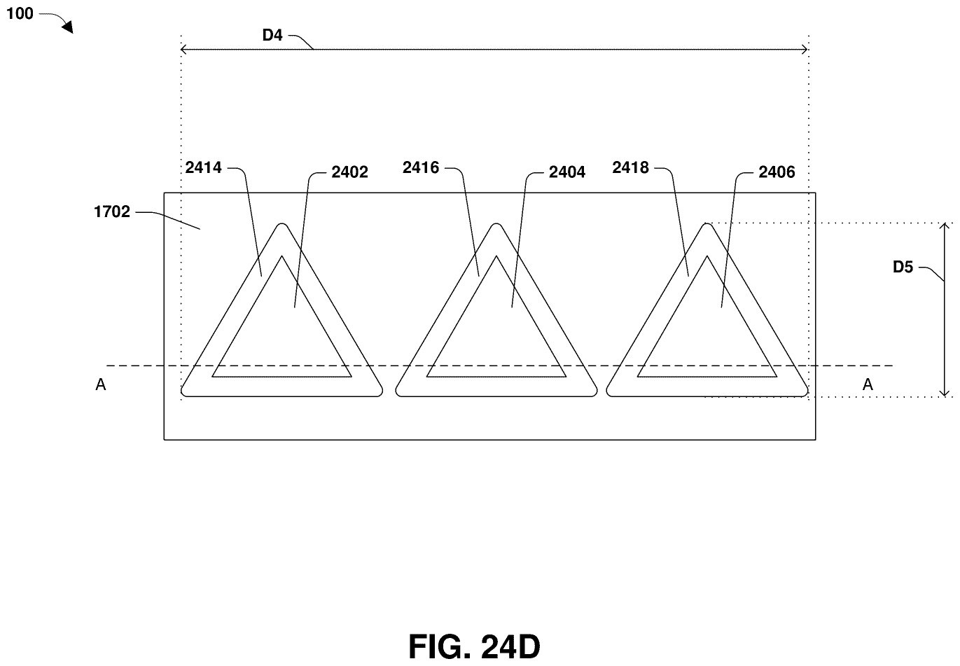

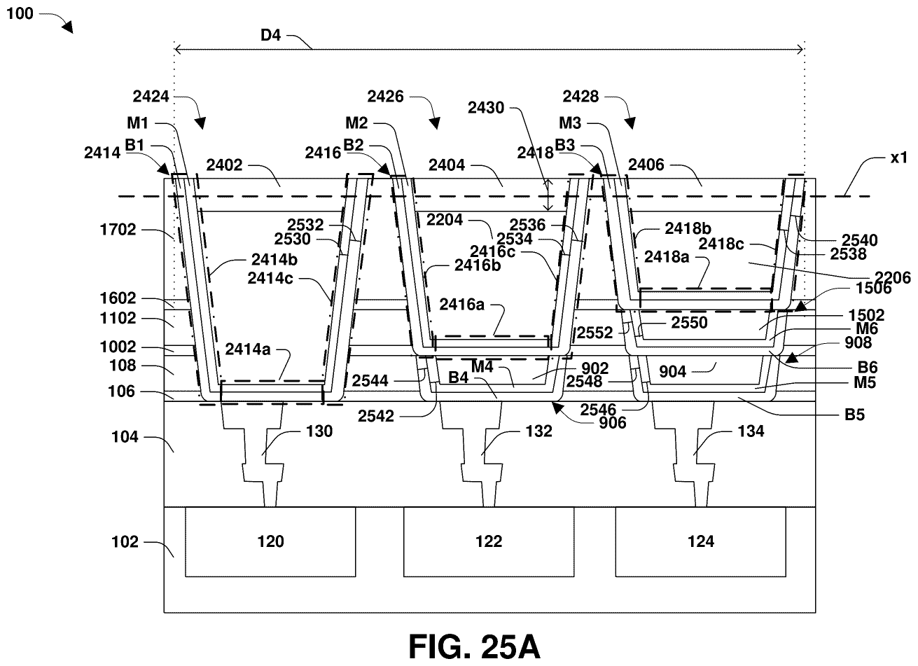

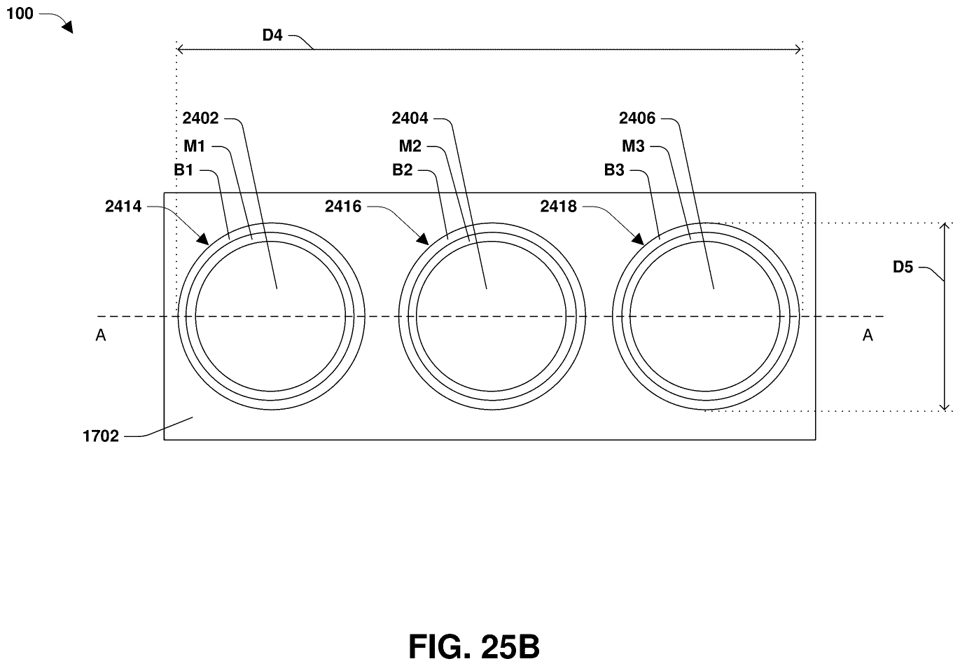

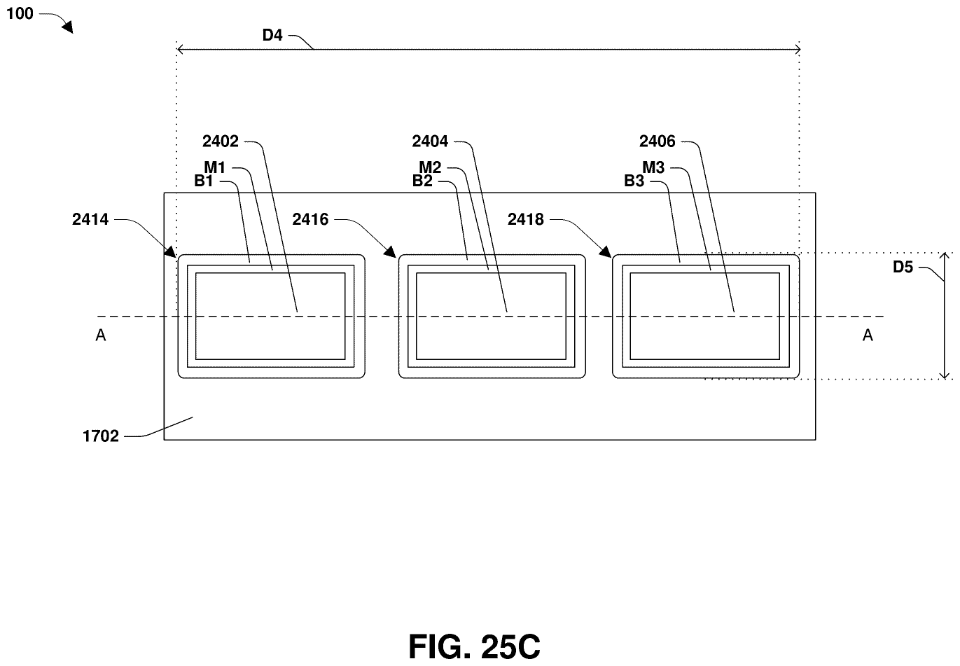

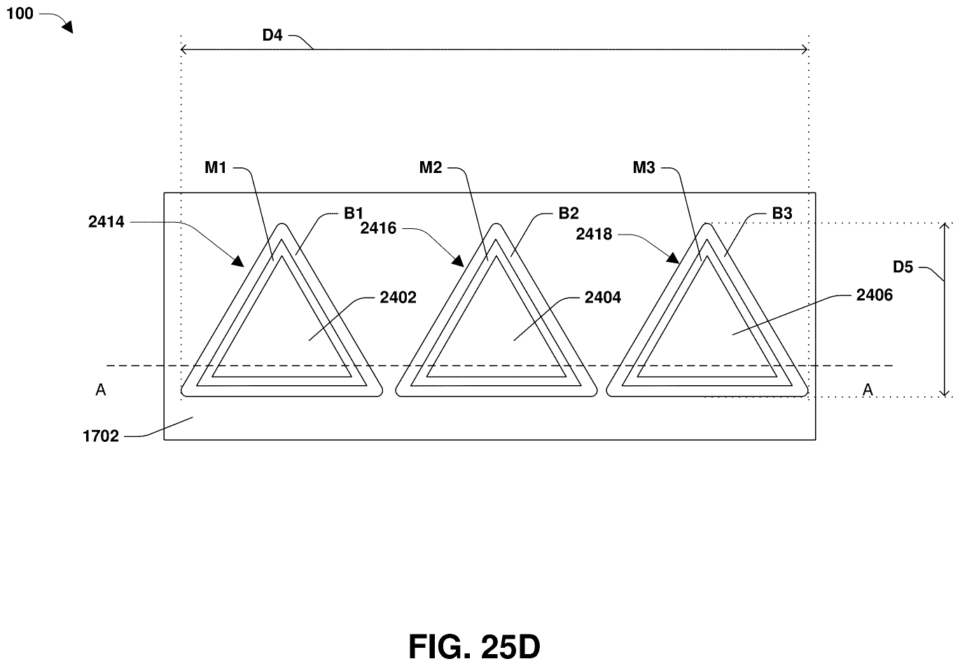

FIGS. 1-26 illustrate a semiconductor device 100 at various stages of fabrication, in accordance with some embodiments. FIGS. 1, 2, 3, 4, 5, 6, 7, 8, 9, 10, 11, 12, 13, 14, 15, 16, 17, 18, 19, 20, 21, 22, 23, 24A, 25A, 26, and 27 illustrate cross-sectional views of the semiconductor device 100. FIGS. 24B-24D illustrate top views of the semiconductor device 100 in various scenarios. The view illustrated in FIG. 24A is a cross-sectional view of the semiconductor device 100 taken along line A-A in FIG. 24B, line A-A in FIG. 24C, or line A-A in FIG. 24D. FIGS. 25B-25D illustrate top views of the semiconductor device 100 in various scenarios. The view illustrated in FIG. 25A is a cross-sectional view of the semiconductor device 100 taken along line A-A in FIG. 25B, line A-A in FIG. 25C, or line A-A in FIG. 25D.

In some embodiments, the semiconductor device 100 comprises a display panel, such as an OLED display panel. In some embodiments, the display panel comprises an array of OLED cells. Other structures and/or configurations of the semiconductor device 100 and/or the display panel are within the scope of the present disclosure.

FIG. 1 illustrates the semiconductor device 100 according to some embodiments. In some embodiments, the semiconductor device 100 comprises at least one of a component layer 102, an interconnection layer 104, a first etch stop layer 106, or a first dielectric layer 108. In some embodiments, the component layer 102 comprises a substrate. In some embodiments, the component layer 102 comprises at least one of an epitaxial layer, a silicon-on-insulator (SOI) structure, a wafer, or a die formed from a wafer. In some embodiments, the component layer 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The component layer 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the component layer 102 are within the scope of the present disclosure. In some embodiments, the component layer 102 comprises dopants having a conductivity type, such as n-type or p-type. In some embodiments, the component layer 102 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques.

In some embodiments, the component layer 102 comprises a front end of line (FEOL) layer of the semiconductor device 100. In some embodiments, OLED-cell driving components are disposed in the component layer 102. In some embodiments, the OLED-cell driving components comprise at least one of first OLED-cell driving circuitry 120, second OLED-cell driving circuitry 122, or third OLED-cell driving circuitry 124. In some embodiments, the first OLED-cell driving circuitry 120 comprises at least one of (i) one or more first transistors, (ii) one or more first capacitors, (iii) one or more first resistors, or (iv) one or more other suitable components. In some embodiments, the second OLED-cell driving circuitry 122 comprises at least one of (i) one or more second transistors, (ii) one or more second capacitors, (iii) one or more second resistors, or (iv) one or more other suitable components. In some embodiments, the third OLED-cell driving circuitry 124 comprises at least one of (i) one or more third transistors, (ii) one or more third capacitors, (iii) one or more third resistors, or (iv) one or more other suitable components.

The interconnection layer 104 is formed over the component layer 102 by at least one of PVD, sputtering, CVD, PECVD, LPCVD, ALCVD, UHVCVD, RPCVD, ALD, MBE, LPE, spin on, growth, or other suitable techniques. In some embodiments, the interconnection layer 104 comprises a back end of line (BEOL) layer of the semiconductor device 100. In some embodiments, the interconnection layer 104 comprises at least one of undoped silicate glass (USG), silicon nitride, phosphosilicate glass (PSG), fluorosilicate glass (FSG), a dielectric material, a low-k dielectric material, an extreme low-k dielectric material, black diamond, or other suitable material. As used herein, the term “low-k dielectric material” refers to a material having a dielectric constant, k, lower than about 3.9. As used herein, the term “extreme low-k dielectric material” refers to a material having a dielectric constant, k, lower than about 2.5. In some embodiments, interconnection components are disposed in the interconnection layer 104. In some embodiments, the interconnection components comprise one or more conductive structures, such as vias, wiring, contacts, metal lines, etc., that provide interconnections between at least one of various doped features, OLED cells, circuitry, input/output, etc. of the semiconductor device 100. In some embodiments, the interconnection components comprise at least one of a first interconnection component 130, a second interconnection component 132, or a third interconnection component 134. In some embodiments, at least one of the first interconnection component 130, the second interconnection component 132, or the third interconnection component 134 comprises one or more metals or other suitable material. In some embodiments, at least one of the first interconnection component 130, the second interconnection component 132, or the third interconnection component 134 comprises copper (Cu).

The first etch stop layer 106 is formed over the interconnection layer 104 by at least one of PVD, sputtering, CVD, PECVD, LPCVD, ALCVD, UHVCVD, RPCVD, ALD, MBE, LPE, spin on, growth, or other suitable techniques. The first etch stop layer 106 at least one of (i) overlies the interconnection layer 104, (ii) is in direct contact with a top surface of the interconnection layer 104, or (iii) is in indirect contact with the top surface of the interconnection layer 104. The first etch stop layer 106 at least one of (i) overlies at least one of the first interconnection component 130, the second interconnection component 132, or the third interconnection component 134, (ii) is in direct contact with a top surface of at least one of the first interconnection component 130, the second interconnection component 132, or the third interconnection component 134, or (iii) is in indirect contact with the top surface of at least one of the first interconnection component 130, the second interconnection component 132, or the third interconnection component 134. In some embodiments, the first etch stop layer 106 comprises at least one of silicon nitride (SiN), silicon carbide (SiC), or other suitable material. A thickness 110 of the first etch stop layer 106 is between about 10 angstroms to about 500,000 angstroms. Other values of the thickness 110 are within the scope of the present disclosure.

The first dielectric layer 108 is formed over the first etch stop layer 106 by at least one of PVD, sputtering, CVD, PECVD, LPCVD, ALCVD, UHVCVD, RPCVD, ALD, MBE, LPE, spin on, growth, or other suitable techniques. The first dielectric layer 108 at least one of (i) overlies the first etch stop layer 106, (ii) is in direct contact with a top surface of the first etch stop layer 106, or (iii) is in indirect contact with the top surface of the first etch stop layer 106. In some embodiments, the first dielectric layer 108 comprises an inter-metal dielectric (IMD) layer. In some embodiments, the first dielectric layer 108 comprises at least one of undoped silicate glass (USG), silicon nitride, phosphosilicate glass (PSG), fluorosilicate glass (FSG), a dielectric material, a low-k dielectric material, an extreme low-k dielectric material, or other suitable material. A thickness 112 of the first dielectric layer 108 is between about 100 angstroms to about 500,000 angstroms. Other values of the thickness 112 are within the scope of the present disclosure.

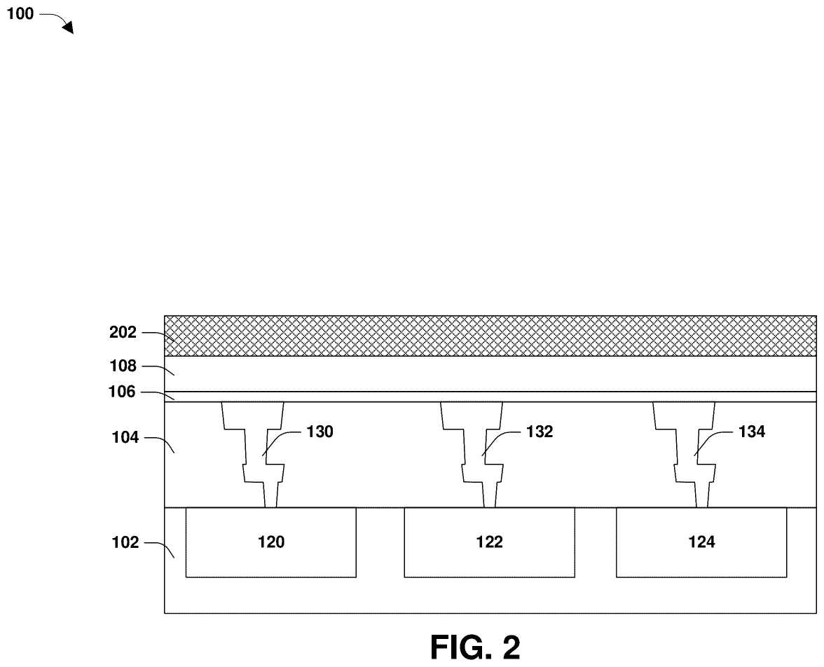

FIG. 2 illustrates a first photoresist 202 formed over the first dielectric layer 108, according to some embodiments. The first photoresist 202 at least one of overlies the first dielectric layer 108, is in direct contact with a top surface of the first dielectric layer 108, or is in indirect contact with the top surface of the first dielectric layer 108. The first photoresist 202 is formed by at least one of PVD, sputtering, CVD, PECVD, LPCVD, ALCVD, UHVCVD, RPCVD, ALD, MBE, LPE, spin on, growth, or other suitable techniques.

In some embodiments, the first photoresist 202 comprises a light-sensitive material, where properties, such as solubility, of the first photoresist 202 are affected by light. The first photoresist 202 is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist.

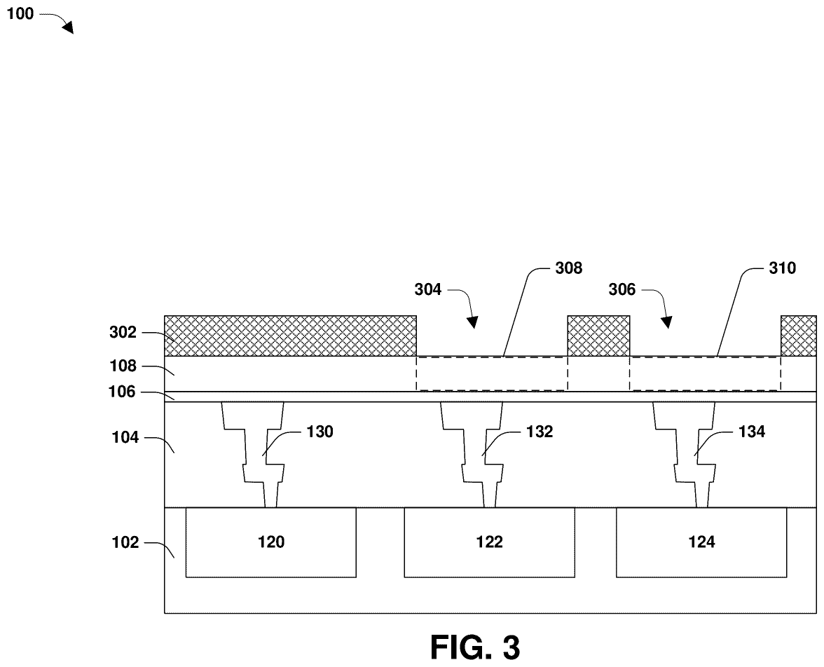

FIG. 3 illustrates a first patterned photoresist 302 formed from the first photoresist 202, according to some embodiments. In some embodiments, the first patterned photoresist 302 defines openings 304 and 306 exposing portions 308 and 310 of the first dielectric layer 108. Even though two openings in the first patterned photoresist 302 are depicted, any number of openings in the first patterned photoresist 302 are contemplated.

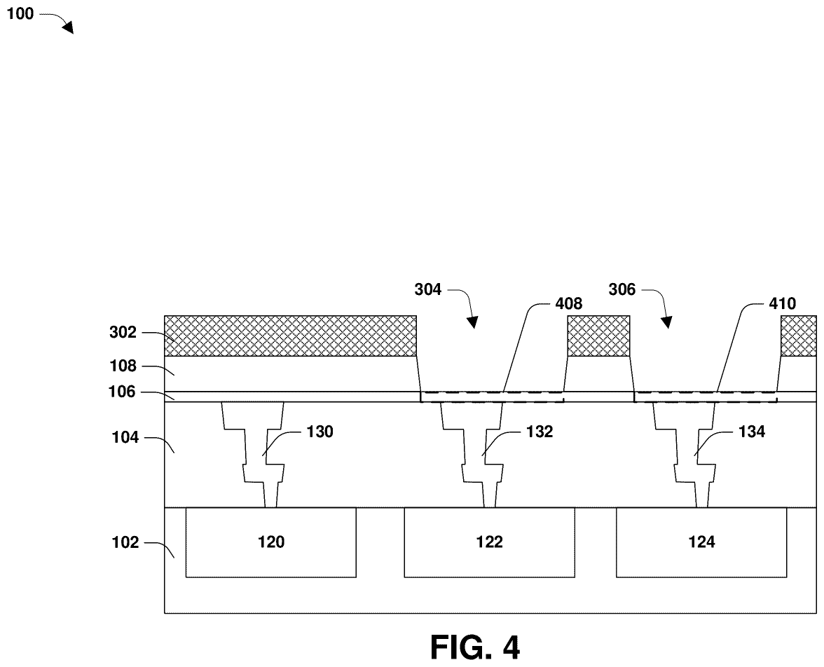

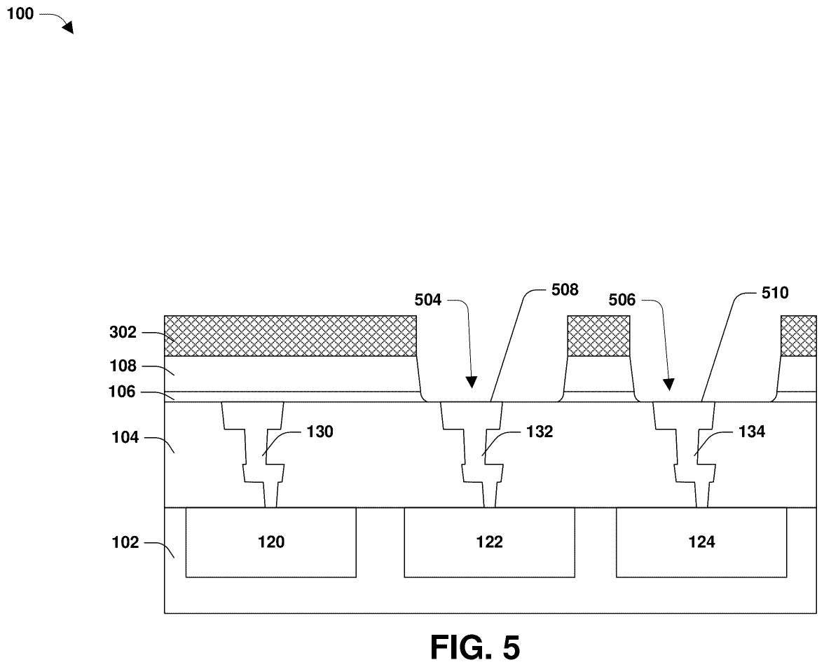

FIGS. 4-5 illustrate use of the first patterned photoresist 302 to form a first set of trenches, according to some embodiments. In some embodiments, a first etching process is performed to remove portions of at least one of the first dielectric layer 108 or the first etch stop layer 106 to form the first set of trenches. In some embodiments, the first set of trenches comprise a first trench 504 and a second trench 506 (shown in FIG. 5). Even though two trenches of the first set of trenches are depicted, any number of trenches of the first set of trenches are contemplated.

In some embodiments, a first etching process is performed to form the first set of trenches, where openings in the first patterned photoresist 302 allow one or more etchants applied during the first etching process to remove portions of at least one of the first dielectric layer 108 or the first etch stop layer 106 while the first patterned photoresist 302 protects or shields portions of the first dielectric layer 108 that are covered by the first patterned photoresist 302 to form the first set of trenches. In some embodiments, the first etching process comprises a first multi-stage etching process comprising a first etching stage and a second etching stage.

In some embodiments, the second etching stage is performed after the first etching stage. In some embodiments, the first etching stage comprises at least one of a dry etching process, a wet etching process, an anisotropic etching process, an isotropic etching process, or other suitable etching process. The first etching stage uses one or more first etching chemicals comprising at least one of plasma, fluorine, hydrogen fluoride (HF), diluted HF, sulfur hexafluoride (SF₆), a chlorine compound such as hydrogen chloride (HCl₂), hydrogen sulfide (H₂S), tetrafluoromethane (CF₄), or other suitable material. The second etching stage uses one or more second etching chemicals comprising at least one of plasma, fluorine, HF, diluted HF, SF₆, a chlorine compound such as HCl₂, H₂S, CF₄, or other suitable material. The one or more first etching chemicals are the same or different than the one or more second etching chemicals. In some embodiments, the second etching stage comprises at least one of a dry etching process, a wet etching process, an anisotropic etching process, an isotropic etching process, or other suitable etching process.

FIG. 4 illustrates use of the first patterned photoresist 302 to perform the first etching stage of the first etching process, according to some embodiments. In some embodiments, the first etching stage comprises removing portions 308 and 310 (shown in FIG. 3) of the first dielectric layer 108 using the one or more first etching chemicals, where openings in the first patterned photoresist 302 allow the one or more first etching chemicals to remove the portions 308 and 310 of the first dielectric layer 108 while the first patterned photoresist 302 protects or shields portions of the first dielectric layer 108 that are covered by the first patterned photoresist 302. In some embodiments, at least one of the first etching stage or the one or more first etching chemicals have an etching selectivity such that the first etching stage removes and/or etches away portions 308 and 310 of the first dielectric layer 108 while removing and/or etching away little to none of the first etch stop layer 106.

FIG. 5 illustrates use of the first patterned photoresist 302 to perform the second etching stage of the first etching process, according to some embodiments. In some embodiments, the second etching stage comprises removing portions 408 and 410 (shown in FIG. 4) of the first etch stop layer 106 using the one or more second etching chemicals, where openings in the first patterned photoresist 302 allow the one or more second etching chemicals to remove the portions 408 and 410 of the first etch stop layer 106 while the first patterned photoresist 302 protects or shields portions of the first dielectric layer 108 and/or the first etch stop layer 106 that are covered by the first patterned photoresist 302. In some embodiments, at least one of the second etching stage or the one or more second etching chemicals have an etching selectivity such that the second etching stage removes and/or etches away portions 408 and 410 of the first etch stop layer 106 while removing and/or etching away little to none of one or more other layers and/or components or the semiconductor device 100, such as at least one of the interconnection layer 104, the first interconnection component 130, the second interconnection component 132, or the third interconnection component 134. In some embodiments, performing the first multi-stage etching process to form the first set of trenches using the first etch stop layer 106 provides for at least one of (i) improved control and accuracy with which the first set of trenches are formed, or (ii) mitigating unwanted etching of and/or damage to a layer and/or component of the semiconductor device 100, such as at least one of the interconnection layer 104, the first interconnection component 130, the second interconnection component 132, or the third interconnection component 134. In some embodiments, the first trench 504 exposes a top surface 508 of the second interconnection component 132. In some embodiments, the second trench 506 exposes a top surface 510 of the third interconnection component 134.

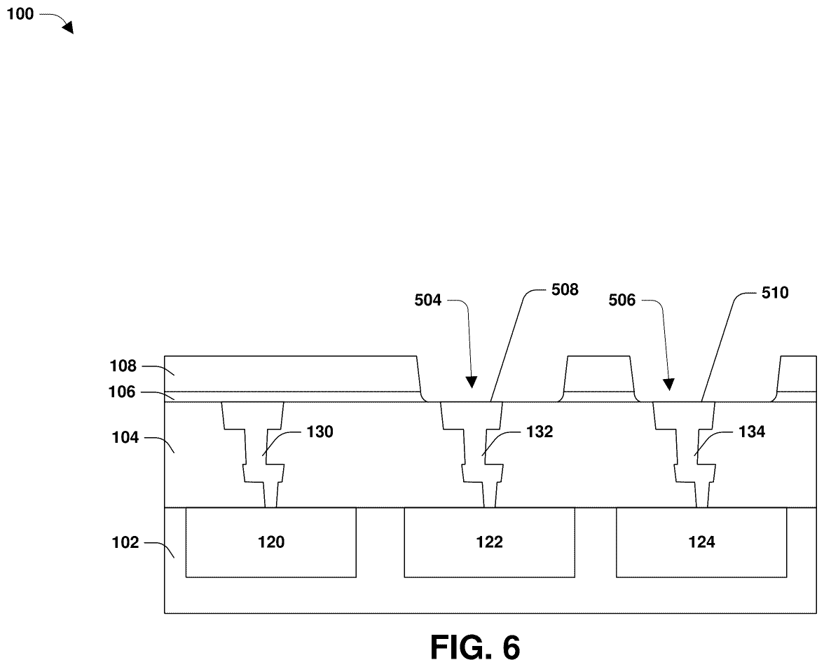

FIG. 6 illustrates removal of the first patterned photoresist 302, according to some embodiments. In some embodiments, the first patterned photoresist 302 is removed after the first set of trenches are formed. The first patterned photoresist 302 is removed by at least one of performing a washing process to wash the first patterned photoresist 302 away, stripping the first patterned photoresist 302 away, etching the first patterned photoresist 302, chemical mechanical planarization (CMP), or other suitable techniques.

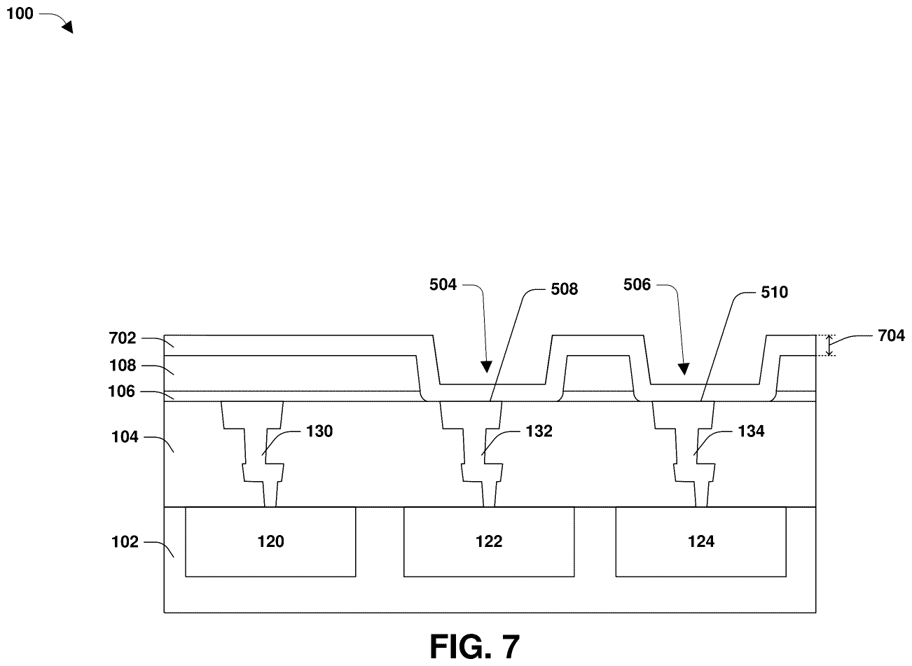

FIG. 7 illustrates a layer 702 formed over the first dielectric layer 108 and/or in the first set of trenches, according to some embodiments. The layer 702 is formed by at least one of PVD, sputtering, CVD, PECVD, LPCVD, ALCVD, UHVCVD, RPCVD, ALD, MBE, LPE, spin on, growth, or other suitable techniques. The layer 702 at least one of (i) overlies the first dielectric layer 108, (ii) is in direct contact with the top surface of the first dielectric layer 108, or (iii) is in indirect contact with the top surface of the first dielectric layer 108. The layer 702 at least one of (i) overlies at least one of the second interconnection component 132 or the third interconnection component 134, (ii) is in direct contact with at least one of the top surface 508 of the second interconnection component 132 or the top surface 510 of the third interconnection component 134, or (iii) is in indirect contact with at least one of the top surface 508 of the second interconnection component 132 or the top surface 510 of the third interconnection component 134. In some embodiments, the layer 702 comprises at least one of tungsten (W), titanium (Ti), tantalum (Ta), copper (Cu), aluminum (Al), aluminum-copper (AlCu), aluminum-silicon-copper (AlSiCu), titanium nitride (TiN), tantalum nitride (TaN), or other suitable material. A thickness 704 of the layer 702 is between about 100 angstroms to about 600,000 angstroms. Other values of the thickness 704 are within the scope of the present disclosure.

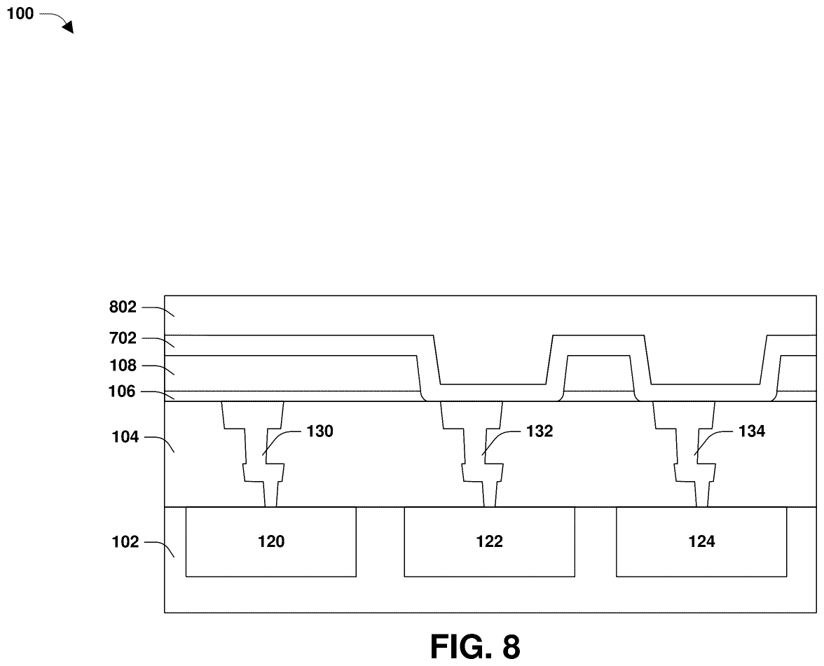

FIG. 8 illustrates a first layer 802 formed over the layer 702, according to some embodiments. The first layer 802 is formed by at least one of PVD, sputtering, CVD, PECVD, LPCVD, ALCVD, UHVCVD, RPCVD, ALD, MBE, LPE, spin on, growth, or other suitable techniques. The first layer 802 at least one of (i) overlies the layer 702, (ii) is in direct contact with the top surface of the layer 702, or (iii) is in indirect contact with the top surface of the layer 702. In some embodiments, the first layer 802 comprises at least one of an oxide semiconductor material, such as silicon oxide, a metal, undoped silicate glass (USG), or other suitable material. In some embodiments, the metal of the first layer 802 comprises at least one of a ferrous metal, aluminum, copper, tungsten, aluminum copper (e.g., aluminum copper with greater than about 99% aluminum content and less than about 1% copper content), or one or more other suitable metals.

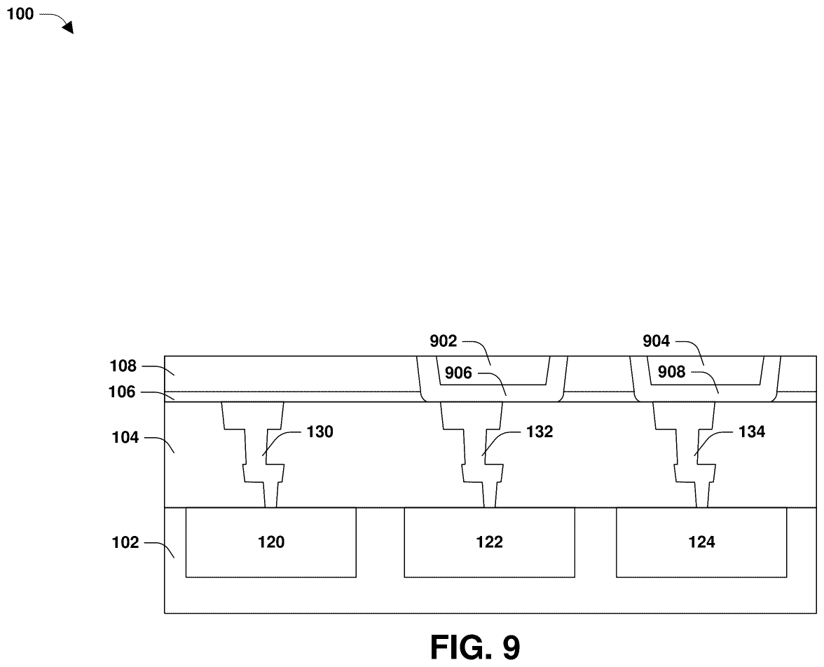

FIG. 9 illustrates removal of portions of at least one of the layer 702 or the first layer 802 (shown in FIG. 8) to form at least one of (i) a first conductive structure 906 comprising a first portion of the layer 702, (ii) a second conductive structure 908 comprising a second portion of the layer 702, (iii) a first filler structure 902 comprising a first portion of the first layer 802, or (iv) a second filler structure 904 comprising a second portion of the first layer 802, according to some embodiments. In some embodiments, the portions of at least one of the layer 702 or the first layer 802 are removed by at least one of chemical mechanical planarization (CMP), etching, a washing process, stripping, or other suitable techniques.

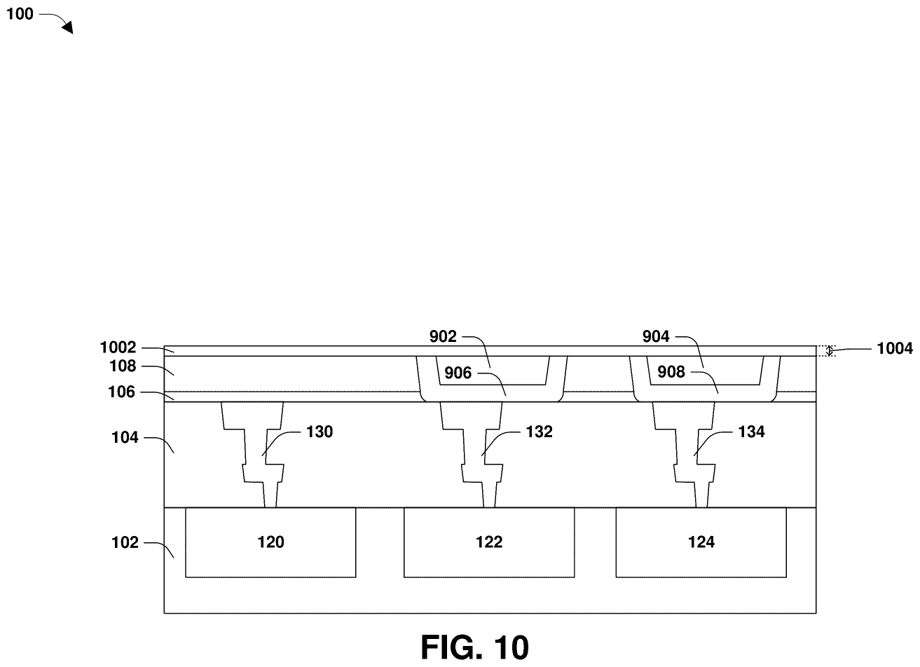

FIG. 10 illustrates a second etch stop layer 1002 formed over the first dielectric layer 108, according to some embodiments. The second etch stop layer 1002 is formed by at least one of PVD, sputtering, CVD, PECVD, LPCVD, ALCVD, UHVCVD, RPCVD, ALD, MBE, LPE, spin on, growth, or other suitable techniques. The second etch stop layer 1002 at least one of (i) overlies the first dielectric layer 108, (ii) is in direct contact with a top surface of the first dielectric layer 108, or (iii) is in indirect contact with the top surface of the first dielectric layer 108. The second etch stop layer 1002 at least one of (i) overlies at least one of the first conductive structure 906, the second conductive structure 908, the first filler structure 902, or the second filler structure 904, (ii) is in direct contact with at least one of a top surface of the first conductive structure 906, a top surface of the second conductive structure 908, a top surface of the first filler structure 902, or a top surface of the second filler structure 904, or (iii) is in indirect contact with at least one of the top surface of the first conductive structure 906, the top surface of the second conductive structure 908, the top surface of the first filler structure 902, or the top surface of the second filler structure 904. In some embodiments, the second etch stop layer 1002 comprises at least one of silicon nitride (SiN), silicon carbide (SiC), or other suitable material. A thickness 1004 of the second etch stop layer 1002 is between about 10 angstroms to about 500,000 angstroms. Other values of the thickness 1004 are within the scope of the present disclosure.

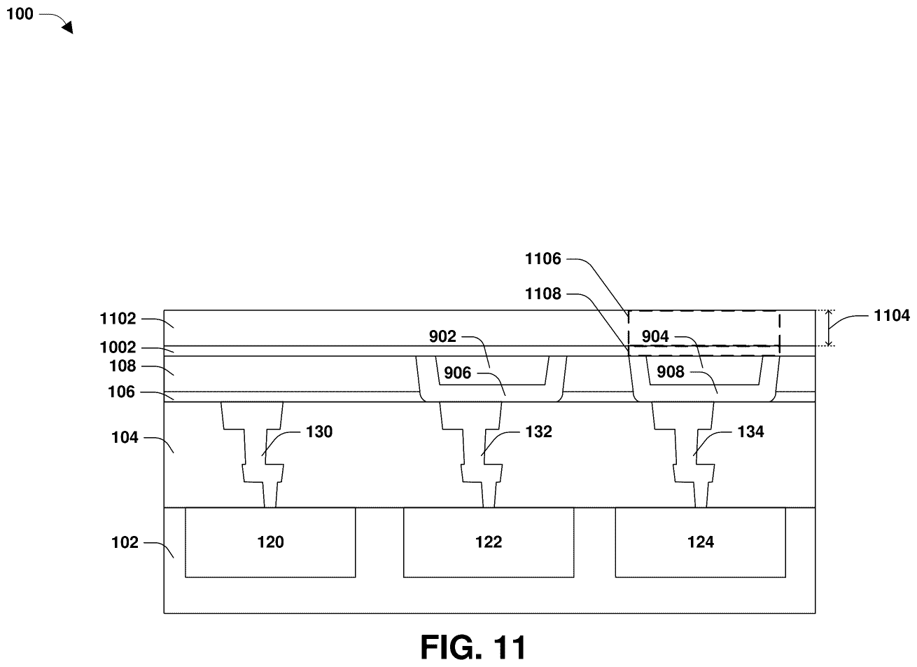

FIG. 11 illustrates a second dielectric layer 1102 formed over the second etch stop layer 1002, according to some embodiments. The second dielectric layer 1102 is formed by at least one of PVD, sputtering, CVD, PECVD, LPCVD, ALCVD, UHVCVD, RPCVD, ALD, MBE, LPE, spin on, growth, or other suitable techniques. The second dielectric layer 1102 at least one of (i) overlies the second etch stop layer 1002, (ii) is in direct contact with a top surface of the second etch stop layer 1002, or (iii) is in indirect contact with the top surface of the second etch stop layer 1002. In some embodiments, the second dielectric layer 1102 comprises an IMD layer. In some embodiments, the second dielectric layer 1102 comprises at least one of undoped silicate glass (USG), silicon nitride, phosphosilicate glass (PSG), fluorosilicate glass (FSG), a dielectric material, a low-k dielectric material, an extreme low-k dielectric material, or other suitable material. A thickness 1104 of the second dielectric layer 1102 is between about 100 angstroms to about 500,000 angstroms. Other values of the thickness 1104 are within the scope of the present disclosure.

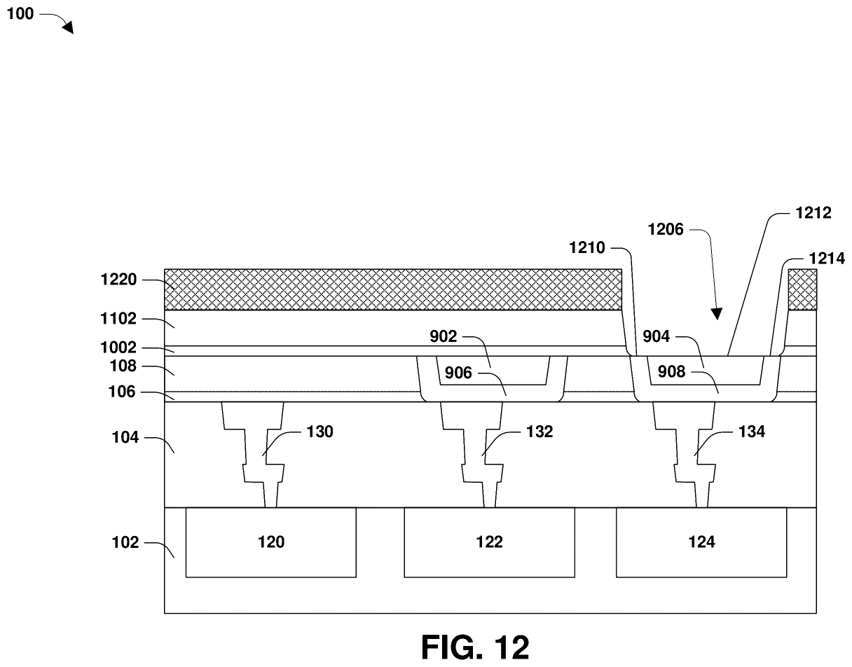

FIG. 12 illustrates a third trench 1206 formed in at least one of the second dielectric layer 1102 or the second etch stop layer 1002, according to some embodiments. In some embodiments, the third trench 1206 is formed using a second photoresist (not shown). The second photoresist is formed over the second dielectric layer 1102. The second photoresist at least one of overlies the second dielectric layer 1102, is in direct contact with a top surface of the second dielectric layer 1102, or is in indirect contact with the top surface of the second dielectric layer 1102. The second photoresist is formed by at least one of PVD, sputtering, CVD, PECVD, LPCVD, ALCVD, UHVCVD, RPCVD, ALD, MBE, LPE, spin on, growth, or other suitable techniques. In some embodiments, the second photoresist is patterned to form a second patterned photoresist 1220 (shown in FIG. 12). In some embodiments, the second patterned photoresist 1220 is used to form the third trench 1206, such as using one or more of the techniques, etching chemicals, etc. provided herein with respect to using the first patterned photoresist 302 to form the first set of trenches. In some embodiments, a second multi-stage etching process is performed to form the third trench 1206, such as using one or more of the techniques, etching chemicals, etc. provided herein with respect to performing the first multi-stage etching process to form the first set of trenches. In some embodiments, performing the second multi-stage etching process to form the third trench 1206 using the second etch stop layer 1002 comprises at least one of (i) performing a third etching stage of the second multi-stage etching process using one or more third etching chemicals (e.g., the one or more first etching chemicals) to remove a portion 1106 (shown in FIG. 11) of the second dielectric layer 1102 or (ii) performing a fourth etching stage of the second multi-stage etching process using one or more fourth etching chemicals (e.g., the one or more second etching chemicals) to remove a portion 1108 (shown in FIG. 11) of the second etch stop layer 1002. In some embodiments, performing the second multi-stage etching process to form the third trench 1206 using the second etch stop layer 1002 provides for at least one of (i) improved control and accuracy with which the third trench 1206 is formed, or (ii) mitigating unwanted etching of and/or damage to a layer and/or component of the semiconductor device 100, such as at least one of the second conductive structure 908 or the second filler structure 904. In some embodiments, the third trench 1206 exposes at least one of a top surface 1210 of the second conductive structure 908, a top surface 1214 of the second conductive structure 908, or a top surface 1212 of the second filler structure 904. In some embodiments, the second patterned photoresist 1220 is removed after the third trench 1206 is formed. The second patterned photoresist 1220 is removed by at least one of performing a washing process to wash the second patterned photoresist 1220 away, stripping the second patterned photoresist 1220 away, etching the second patterned photoresist 1220, chemical mechanical planarization (CMP), or other suitable techniques.

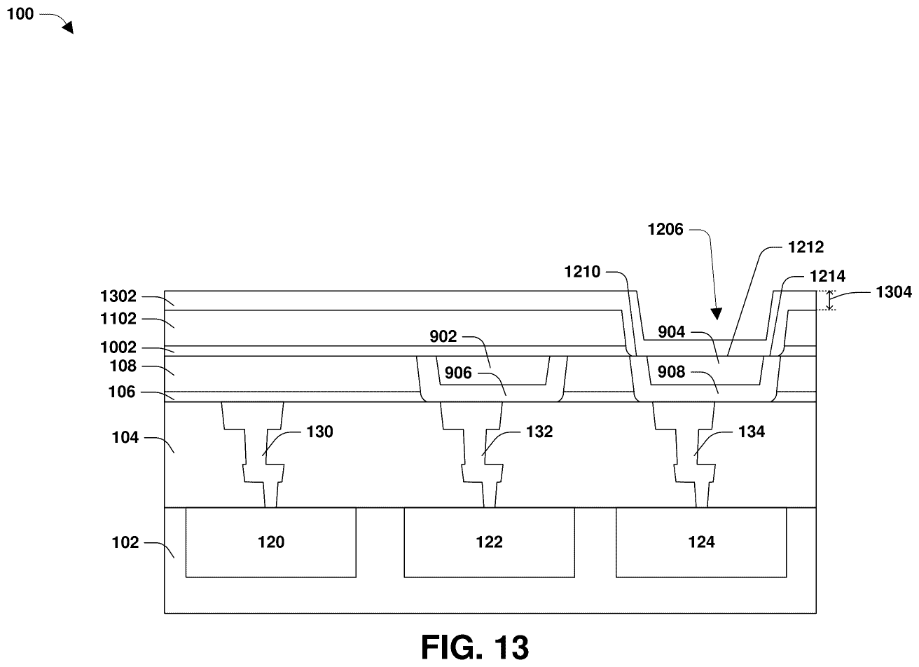

FIG. 13 illustrates a layer 1302 formed over the second dielectric layer 1102 and/or in the third trench 1206, according to some embodiments. The layer 1302 is formed by at least one of PVD, sputtering, CVD, PECVD, LPCVD, ALCVD, UHVCVD, RPCVD, ALD, MBE, LPE, spin on, growth, or other suitable techniques.

The layer 1302 at least one of (i) overlies the second dielectric layer 1102, (ii) is in direct contact with the top surface of the second dielectric layer 1102, or (iii) is in indirect contact with the top surface of the second dielectric layer 1102. The layer 1302 at least one of (i) overlies at least one of the second conductive structure 908 or the second filler structure 904, (ii) is in direct contact with at least one of the top surface 1210 of the second conductive structure 908, the top surface 1214 of the second conductive structure 908, or the top surface 1212 of the second filler structure 904, or (iii) is in indirect contact with at least one of the top surface 1210 of the second conductive structure 908, the top surface 1214 of the second conductive structure 908, or the top surface 1212 of the second filler structure 904. In some embodiments, the layer 1302 comprises at least one of tungsten (W), titanium (Ti), tantalum (Ta), copper (Cu), aluminum (Al), aluminum-copper (AlCu), aluminum-silicon-copper (AlSiCu), titanium nitride (TiN), tantalum nitride (TaN), or other suitable material. A thickness 1304 of the layer 1302 is between about 100 angstroms to about 600,000 angstroms. Other values of the thickness 1304 are within the scope of the present disclosure.

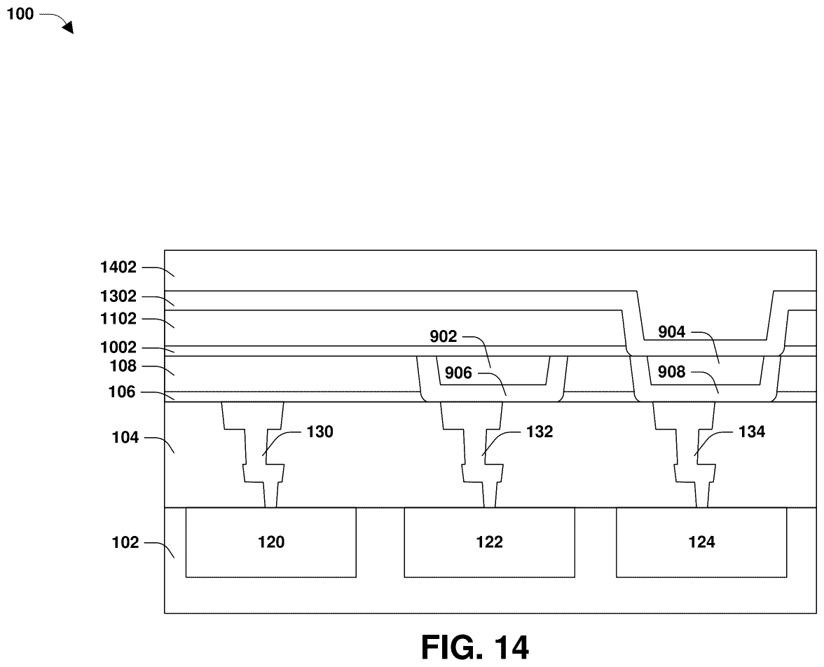

FIG. 14 illustrates a second layer 1402 formed over the layer 1302, according to some embodiments. The second layer 1402 is formed by at least one of PVD, sputtering, CVD, PECVD, LPCVD, ALCVD, UHVCVD, RPCVD, ALD, MBE, LPE, spin on, growth, or other suitable techniques. The second layer 1402 at least one of (i) overlies the layer 1302, (ii) is in direct contact with the top surface of the layer 1302, or (iii) is in indirect contact with the top surface of the layer 1302. In some embodiments, the second layer 1402 comprises at least one of an oxide semiconductor material, such as silicon oxide, a metal, undoped silicate glass (USG), or other suitable material. In some embodiments, the metal of the second layer 1402 comprises at least one of a ferrous metal, aluminum, copper, tungsten, aluminum copper (e.g., aluminum copper with greater than about 99% aluminum content and less than about 1% copper content), or one or more other suitable metals.

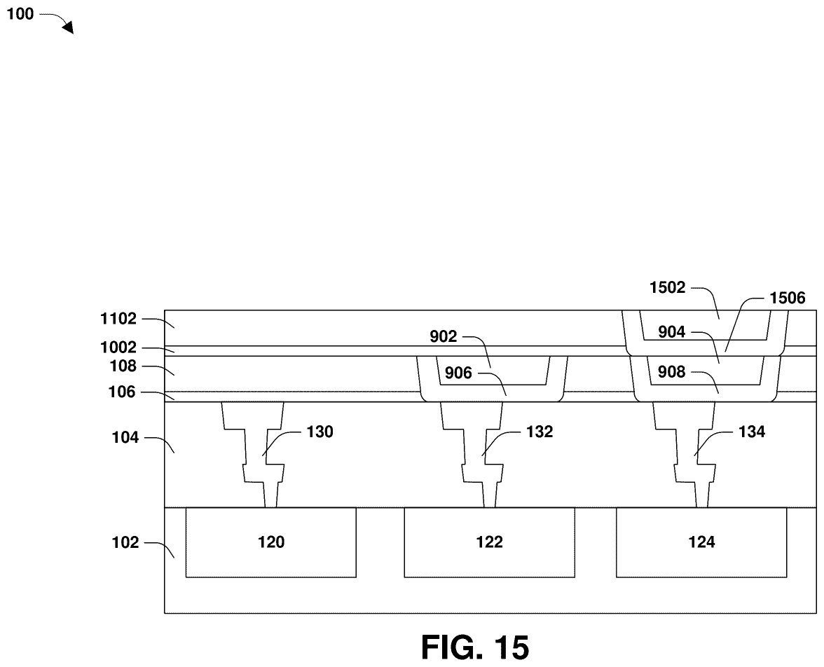

FIG. 15 illustrates removal of portions of at least one of the layer 1302 or the second layer 1402 (shown in FIG. 14) to form at least one of (i) a third conductive structure 1506 comprising a portion of the layer 1302, or (ii) a third filler structure 1502 comprising a portion of the second layer 1402, according to some embodiments. In some embodiments, the portions of at least one of the layer 1302 or the second layer 1402 are removed by at least one of chemical mechanical planarization (CMP), etching, a washing process, stripping, or other suitable techniques.

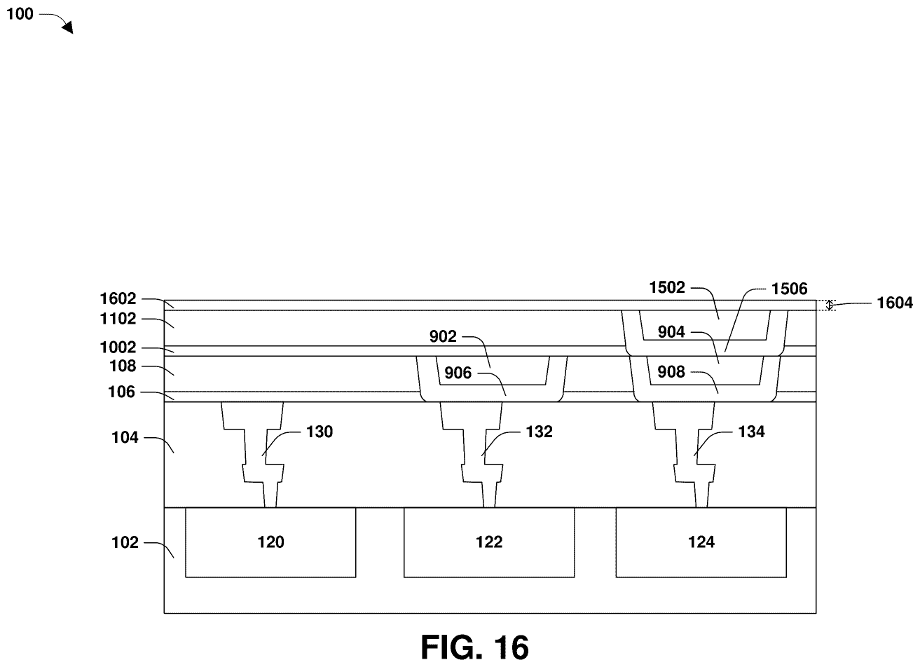

FIG. 16 illustrates a third etch stop layer 1602 formed over the second dielectric layer 1102, according to some embodiments. The third etch stop layer 1602 is formed by at least one of PVD, sputtering, CVD, PECVD, LPCVD, ALCVD, UHVCVD, RPCVD, ALD, MBE, LPE, spin on, growth, or other suitable techniques. The third etch stop layer 1602 at least one of (i) overlies the second dielectric layer 1102, (ii) is in direct contact with a top surface of the second dielectric layer 1102, or (iii) is in indirect contact with the top surface of the second dielectric layer 1102. The third etch stop layer 1602 at least one of (i) overlies at least one of the third conductive structure 1506 or the third filler structure 1502, (ii) is in direct contact with at least one of a top surface of the third conductive structure 1506 or a top surface of the third filler structure 1502, or (iii) is in indirect contact with at least one of the top surface of the third conductive structure 1506 or the top surface of the third filler structure 1502. In some embodiments, the third etch stop layer 1602 comprises at least one of silicon nitride (SiN), silicon carbide (SiC), or other suitable material. A thickness 1604 of the third etch stop layer 1602 is between about 10 angstroms to about 500,000 angstroms. Other values of the thickness 1604 are within the scope of the present disclosure.

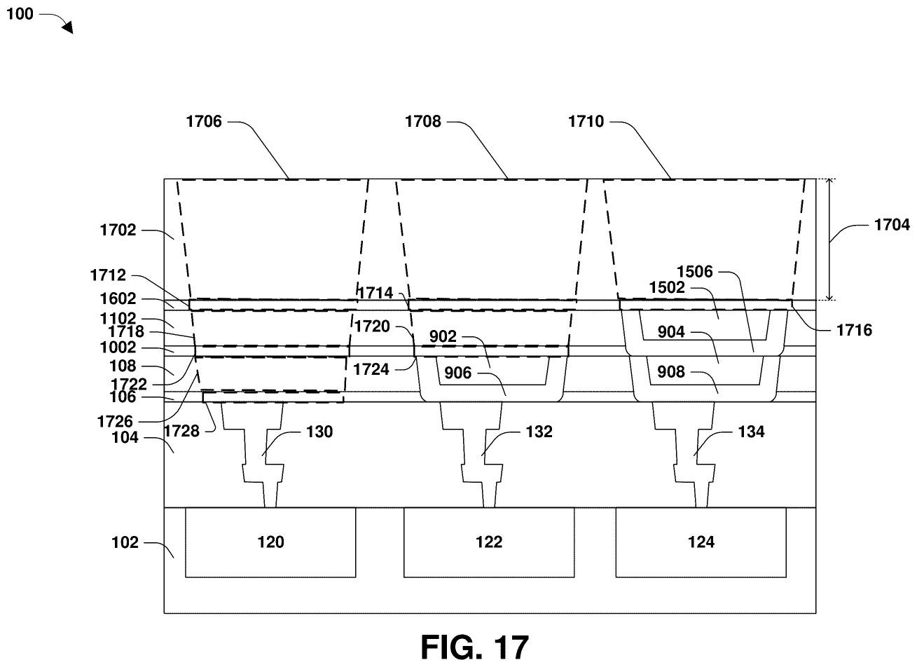

FIG. 17 illustrates a third dielectric layer 1702 formed over the third etch stop layer 1602, according to some embodiments. The third dielectric layer 1702 is formed by at least one of PVD, sputtering, CVD, PECVD, LPCVD, ALCVD, UHVCVD, RPCVD, ALD, MBE, LPE, spin on, growth, or other suitable techniques. The third dielectric layer 1702 at least one of (i) overlies the third etch stop layer 1602, (ii) is in direct contact with a top surface of the third etch stop layer 1602, or (iii) is in indirect contact with the top surface of the third etch stop layer 1602. In some embodiments, the third dielectric layer 1702 comprises an IMD layer. In some embodiments, the third dielectric layer 1702 comprises at least one of undoped silicate glass (USG), silicon nitride, phosphosilicate glass (PSG), fluorosilicate glass (FSG), a dielectric material, a low-k dielectric material, an extreme low-k dielectric material, or other suitable material. A thickness 1704 of the third dielectric layer 1702 is between about 100 angstroms to about 500,000 angstroms. Other values of the thickness 1704 are within the scope of the present disclosure. A first ratio of the thickness 1704 of the third dielectric layer 1702 to the thickness 1104 of the second dielectric layer 1102 is between about 1:1 to about 5000:1. Other values of the first ratio are within the scope of the present disclosure.

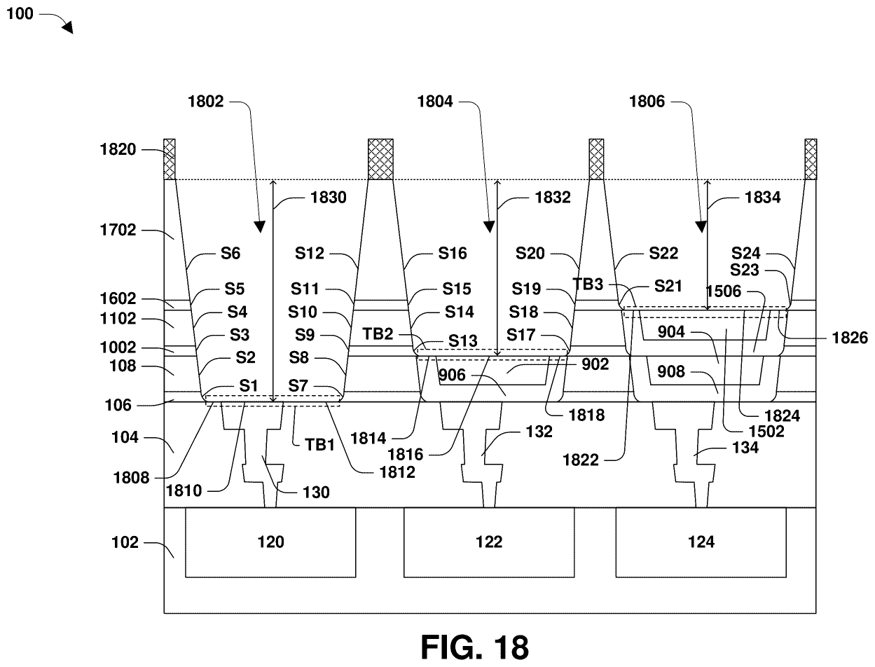

FIG. 18 illustrates a second set of trenches formed in at least one of the third dielectric layer 1702 or the third etch stop layer 1602, according to some embodiments. In some embodiments, the second set of trenches comprises at least one of a fourth trench 1802, a fifth trench 1804, or a sixth trench 1806. Even though three trenches of the second set of trenches are depicted, any number of trenches of the second set of trenches are contemplated.

In some embodiments, the second set of trenches is formed using a third photoresist (not shown). The third photoresist is formed over the third dielectric layer 1702. The third photoresist at least one of overlies the third dielectric layer 1702, is in direct contact with a top surface of the third dielectric layer 1702, or is in indirect contact with the top surface of the third dielectric layer 1702. The third photoresist is formed by at least one of PVD, sputtering, CVD, PECVD, LPCVD, ALCVD, UHVCVD, RPCVD, ALD, MBE, LPE, spin on, growth, or other suitable techniques.

In some embodiments, the third photoresist is patterned to form a third patterned photoresist 1820. In some embodiments, the third patterned photoresist 1820 is used to form the second set of trenches, such as using one or more of the techniques, etching chemicals, etc. provided herein with respect to using the first patterned photoresist 302 to form the first set of trenches. In some embodiments, a third multi-stage etching process is performed to form the second set of trenches, such as using one or more of the techniques, etching chemicals, etc. provided herein with respect to performing the first multi-stage etching process to form the first set of trenches. In some embodiments, performing the third multi-stage etching process to form the second set of trenches comprises at least one of (i) performing a fifth etching stage of the third multi-stage etching process using one or more fifth etching chemicals (e.g., the one or more first etching chemicals) to remove at least one of a portion 1706 (shown in FIG. 17) of the third dielectric layer 1702, a portion 1708 of the third dielectric layer 1702, or a portion 1710 of the third dielectric layer 1702, (ii) performing a sixth etching stage of the third multi-stage etching process using one or more sixth etching chemicals (e.g., the one or more second etching chemicals) to remove at least one of a portion 1712 (shown in FIG. 17) of the third etch stop layer 1602, a portion 1714 of the third etch stop layer 1602, or a portion 1716 of the third etch stop layer 1602, (iii) performing a seventh etching stage of the third multi-stage etching process using one or more seventh etching chemicals (e.g., the one or more first etching chemicals) to remove at least one of a portion 1718 (shown in FIG. 17) of the second dielectric layer 1102 or a portion 1720 of the second dielectric layer 1102, (iv) performing an eighth etching stage of the third multi-stage etching process using one or more eighth etching chemicals (e.g., the one or more second etching chemicals) to remove at least one of a portion 1722 (shown in FIG. 17) of the second etch stop layer 1002 or a portion 1724 of the second etch stop layer 1002, (v) performing a ninth etching stage of the third multi-stage etching process using one or more ninth etching chemicals (e.g., the one or more first etching chemicals) to remove a portion 1726 (shown in FIG. 17) of the first dielectric layer 108, or (vi) performing a tenth etching stage of the third multi-stage etching process using one or more tenth etching chemicals (e.g., the one or more second etching chemicals) to remove a portion 1728 (shown in FIG. 17) of the first etch stop layer 106. In some embodiments, performing the third multi-stage etching process to form the second set of trenches using the third etch stop layer 1602 provides for at least one of (i) improved control and accuracy with which the second set of trenches is formed, or (ii) mitigating unwanted etching of and/or damage to a layer and/or component of the semiconductor device 100, such as at least one of the first interconnection component 130, the first conductive structure 906, the first filler structure 902, the third conductive structure 1506, or the third filler structure 1502. In some embodiments, the third patterned photoresist 1820 is removed after the second set of trenches is formed. The third patterned photoresist 1820 is removed by at least one of performing a washing process to wash the third patterned photoresist 1820 away, stripping the third patterned photoresist 1820 away, etching the third patterned photoresist 1820, chemical mechanical planarization (CMP), or other suitable techniques.

In some embodiments, the fourth trench 1802 is defined by at least one of a sidewall S1 of the first etch stop layer 106, a sidewall S2 of the first dielectric layer 108, a sidewall S3 of the second etch stop layer 1002, a sidewall S4 of the second dielectric layer 1102, a sidewall S5 of the third etch stop layer 1602, a sidewall S6 of the third dielectric layer 1702, a sidewall S7 of the first etch stop layer 106, a sidewall S8 of the first dielectric layer 108, a sidewall S9 of the second etch stop layer 1002, a sidewall S10 of the second dielectric layer 1102, a sidewall S11 of the third etch stop layer 1602, a sidewall S12 of the third dielectric layer 1702, or a trench base TB1. In some embodiments, the trench base TB1 of the fourth trench 1802 comprises at least one of an exposed surface 1808 of the interconnection layer 104, an exposed surface 1810 of the first interconnection component 130, or an exposed surface 1812 of the interconnection layer 104. In some embodiments, at least one of the sidewall S1, the sidewall S2, the sidewall S3, the sidewall S4, the sidewall S5, the sidewall S6, the sidewall S7, the sidewall S8, the sidewall S9, the sidewall S10, the sidewall S11, or the sidewall S12 is tapered. In some embodiments, at least one of the sidewall S1, the sidewall S2, the sidewall S3, the sidewall S4, the sidewall S5, or the sidewall S6 is tapered to have a negative slope and at least one of the sidewall S7, the sidewall S8, the sidewall S9, the sidewall S10, the sidewall S11, or the sidewall S12 is tapered to have a positive slope.

In some embodiments, the fifth trench 1804 is defined by at least one of a sidewall S13 of the second etch stop layer 1002, a sidewall S14 of the second dielectric layer 1102, a sidewall S15 of the third etch stop layer 1602, a sidewall S16 of the third dielectric layer 1702, a sidewall S17 of the second etch stop layer 1002, a sidewall S18 of the second dielectric layer 1102, a sidewall S19 of the third etch stop layer 1602, a sidewall S20 of the third dielectric layer 1702, or a trench base TB2. In some embodiments, the trench base TB2 of the fifth trench 1804 comprises at least one of an exposed surface 1814 of the first conductive structure 906, an exposed surface 1816 of the first filler structure 902, or an exposed surface 1818 of the first conductive structure 906. In some embodiments, at least one of the sidewall S13, the sidewall S14, the sidewall S15, the sidewall S16, the sidewall S17, the sidewall S18, the sidewall S19, or the sidewall S20 is tapered. In some embodiments, at least one of the sidewall S13, the sidewall S14, the sidewall S15, or the sidewall S16 is tapered to have a negative slope and at least one of the sidewall S17, the sidewall S18, the sidewall S19, or the sidewall S20 is tapered to have a positive slope.

In some embodiments, the sixth trench 1806 is defined by at least one of a sidewall S21 of the third etch stop layer 1602, a sidewall S22 of the third dielectric layer 1702, a sidewall S23 of the third etch stop layer 1602, a sidewall S24 of the third dielectric layer 1702, or a trench base TB3. In some embodiments, the trench base TB3 of the sixth trench 1806 comprises at least one of an exposed surface 1822 of the third conductive structure 1506, an exposed surface 1824 of the third filler structure 1502, or an exposed surface 1826 of the third conductive structure 1506. In some embodiments, at least one of the sidewall S21, the sidewall S22, the sidewall S23, or the sidewall S24 is tapered. In some embodiments, at least one of the sidewall S21 or the sidewall S22 is tapered to have a negative slope and at least one of the sidewall S23 or the sidewall S24 is tapered to have a positive slope.

In some embodiments, an elevation of the trench base TB1 of the fourth trench 1802 is different than (e.g., lower than) at least one of an elevation of the trench base TB2 of the fifth trench 1804 or an elevation of the trench base TB3 of the sixth trench 1806. In some embodiments, the elevation of the trench base TB2 of the fifth trench 1804 is different than (e.g., lower than) the elevation of the trench base TB3 of the sixth trench 1806.

A second ratio of a depth 1830 of the fourth trench 1802 to a depth 1832 of the fifth trench 1804 is between about 1.5:1 to about 27000:1. A third ratio of the depth 1830 of the fourth trench 1802 to a depth 1834 of the sixth trench 1806 is between about 3:1 to about 27000:1. A fourth ratio of the depth 1832 of the fifth trench 1804 to the depth 1834 of the sixth trench 1806 is between about 2:1 to about 18000:1. Other values of the second ratio, the third ratio, and the fourth ratio are within the scope of the present disclosure.

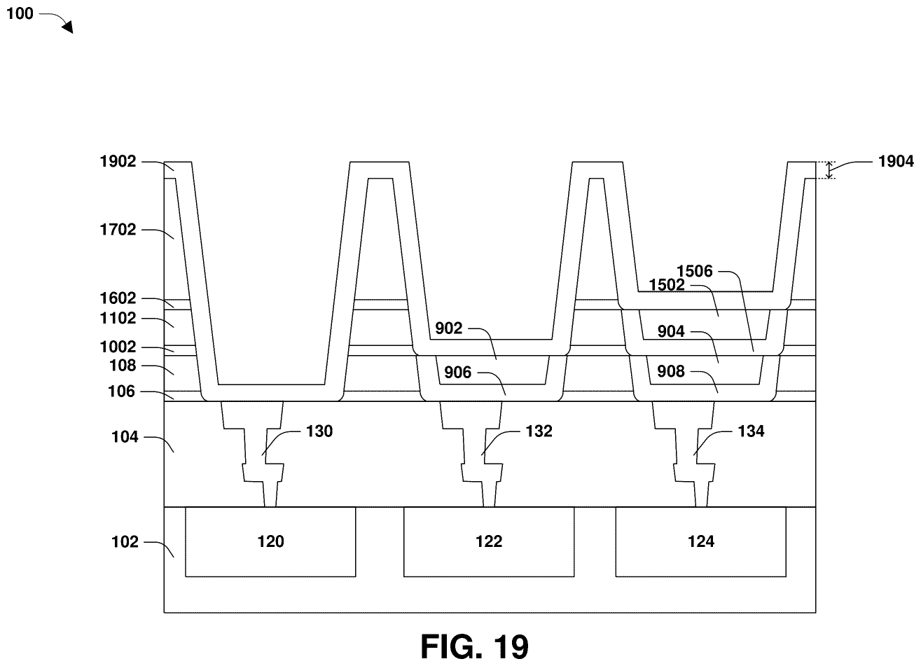

FIG. 19 illustrates a reflective layer 1902 formed over the second dielectric layer 1102 and/or in the third trench 1206, according to some embodiments. The reflective layer 1902 is formed by at least one of PVD, sputtering, CVD, PECVD, LPCVD, ALCVD, UHVCVD, RPCVD, ALD, MBE, LPE, spin on, growth, or other suitable techniques. The reflective layer 1902 at least one of (i) is aligned with at least one of the trench base TB1 (shown in FIG. 18) of the fourth trench 1802, the trench base TB2 of the fifth trench 1804, the trench base TB3 of the sixth trench 1806 of the fourth trench 1802, the sidewall S1, the sidewall S2, the sidewall S3, the sidewall S4, the sidewall S5, the sidewall S6, the sidewall S7, the sidewall S8, the sidewall S9, the sidewall S10, the sidewall S11, the sidewall S12, the sidewall S13, the sidewall S14, the sidewall S15, the sidewall S16, the sidewall S17, the sidewall S18, the sidewall S19, the sidewall S20, the sidewall S21, the sidewall S22, the sidewall S23, or the sidewall S24, (ii) is in direct contact with at least one of the trench base TB1 (shown in FIG. 18) of the fourth trench 1802, the trench base TB2 of the fifth trench 1804, the trench base TB3 of the sixth trench 1806 of the fourth trench 1802, the sidewall S1, the sidewall S2, the sidewall S3, the sidewall S4, the sidewall S5, the sidewall S6, the sidewall S7, the sidewall S8, the sidewall S9, the sidewall S10, the sidewall S11, the sidewall S12, the sidewall S13, the sidewall S14, the sidewall S15, the sidewall S16, the sidewall S17, the sidewall S18, the sidewall S19, the sidewall S20, the sidewall S21, the sidewall S22, the sidewall S23, or the sidewall S24, or (iii) is in indirect contact with at least one of the trench base TB1 (shown in FIG. 18) of the fourth trench 1802, the trench base TB2 of the fifth trench 1804, the trench base TB3 of the sixth trench 1806 of the fourth trench 1802, the sidewall S1, the sidewall S2, the sidewall S3, the sidewall S4, the sidewall S5, the sidewall S6, the sidewall S7, the sidewall S8, the sidewall S9, the sidewall S10, the sidewall S11, the sidewall S12, the sidewall S13, the sidewall S14, the sidewall S15, the sidewall S16, the sidewall S17, the sidewall S18, the sidewall S19, the sidewall S20, the sidewall S21, the sidewall S22, the sidewall S23, or the sidewall S24. In some embodiments, the reflective layer 1902 comprises at least one of tungsten (W), titanium (Ti), tantalum (Ta), copper (Cu), aluminum (Al), aluminum-copper (AlCu), aluminum-silicon-copper (AlSiCu), titanium nitride (TiN), tantalum nitride (TaN), or other suitable material. A thickness 1904 of the reflective layer 1902 is between about 100 angstroms to about 600,000 angstroms. Other values of the thickness 1904 are within the scope of the present disclosure.

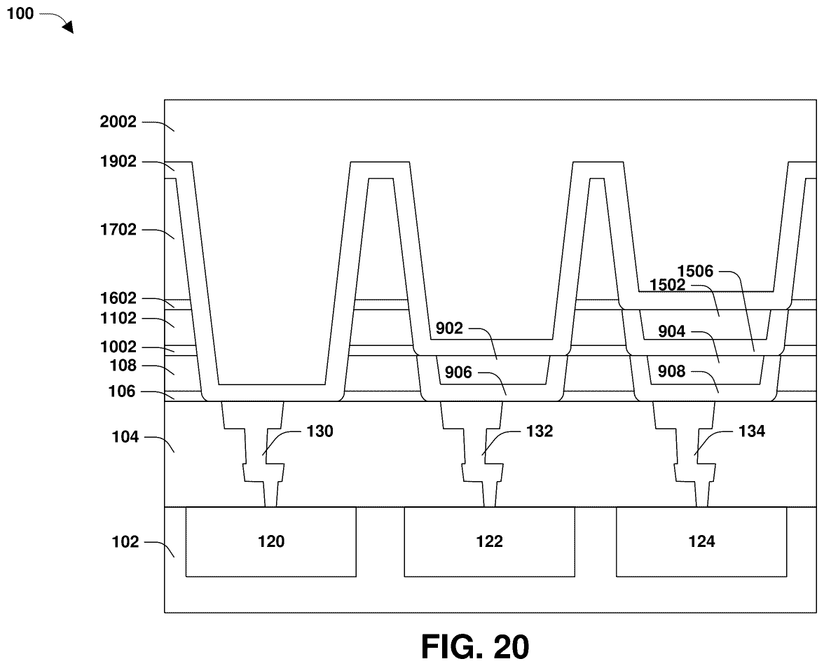

FIG. 20 illustrates an optical resonation layer 2002 formed over the reflective layer 1902, according to some embodiments. The optical resonation layer 2002 is formed by at least one of PVD, sputtering, CVD, PECVD, LPCVD, ALCVD, UHVCVD, RPCVD, ALD, MBE, LPE, spin on, growth, or other suitable techniques. The optical resonation layer 2002 at least one of (i) overlies the reflective layer 1902, (ii) is in direct contact with the reflective layer 1902, or (iii) is in indirect contact with the reflective layer 1902. In some embodiments, the optical resonation layer 2002 comprises at least one of an oxide semiconductor material, such as silicon oxide, a nitride semiconductor material, such as silicon nitride, undoped silicate glass (USG), phosphosilicate glass (PSG), fluorosilicate glass (FSG), a low-k dielectric material, an extreme low-k dielectric material, black diamond, or other suitable material. In some embodiments, the optical resonation layer 2002 comprises a transparent material.

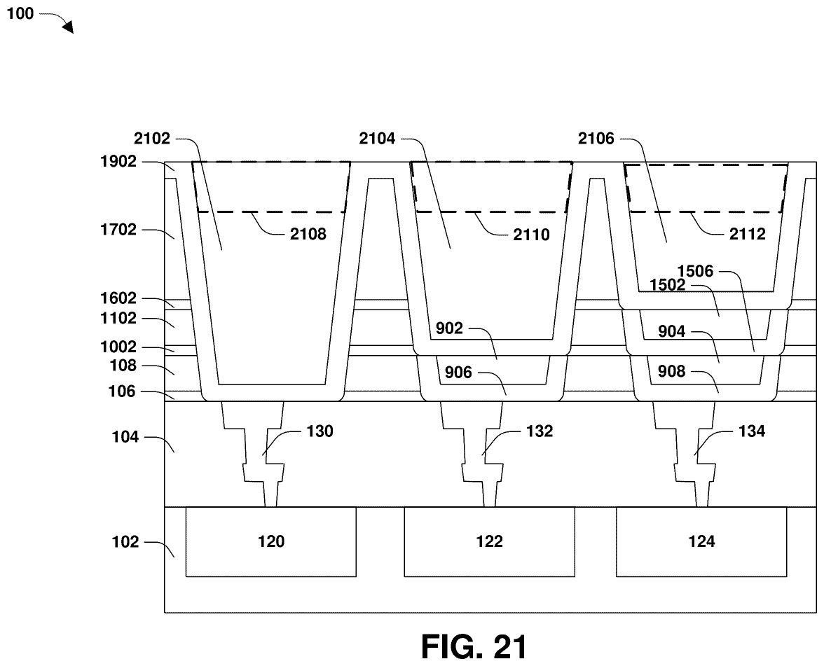

FIG. 21 illustrates removal of portions of at least one of the reflective layer 1902 or the optical resonation layer 2002 (shown in FIG. 20) to form at least one of (i) a first structure 2102 comprising a first portion of the optical resonation layer 2002, (ii) a second structure 2104 comprising a second portion of the optical resonation layer 2002, or (iii) a third structure 2106 comprising a third portion of the optical resonation layer 2002, according to some embodiments. In some embodiments, the portions of at least one of the reflective layer 1902 or the optical resonation layer 2002 are removed by at least one of chemical mechanical planarization (CMP), etching, a washing process, stripping, or other suitable techniques.

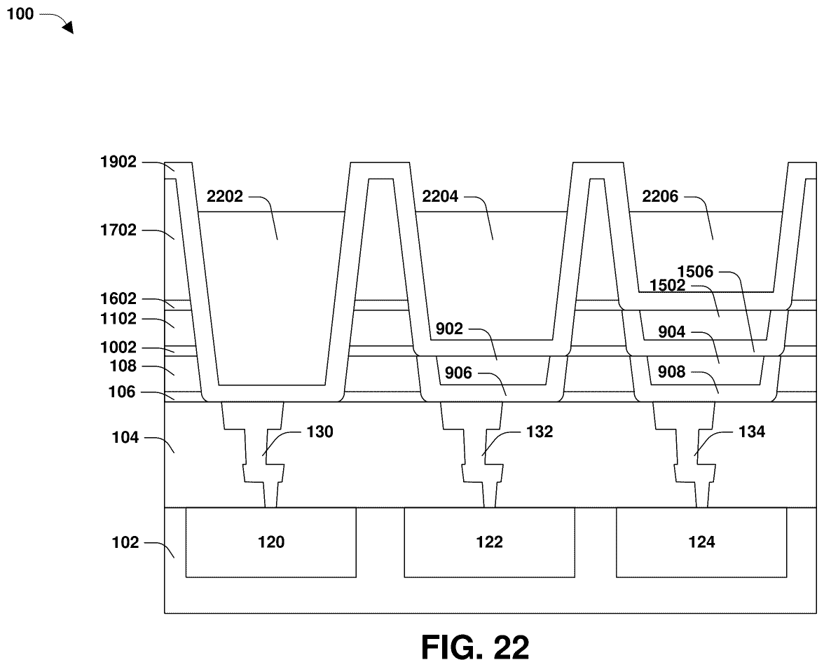

FIG. 22 illustrates removal of portions 2108, 2110, and 2112 (shown in FIG. 21) of the first structure 2102, the second structure 2104, and the third structure 2106, respectively, to form a set of optical resonation structures comprising at least one of a first optical resonation structure 2202 comprising a portion of the first structure 2102, (ii) a second optical resonation structure 2204 comprising a portion of the second structure 2104, or (iii) a third optical resonation structure 2206 comprising a portion of the third structure 2106, according to some embodiments. Even though three optical resonation structures of the set of optical resonation structures are depicted, any number of optical resonation structures of the set of optical resonation structures are contemplated. In some embodiments, the portions 2108, 2110, and 2112 are removed by a wet etchant dipping process in which the semiconductor device 100 is dipped in an etching fluid comprising one or more etching chemicals, such as at least one of HF, diluted HF, or other suitable material. In some embodiments, the reflective layer 1902 acts as a protective mask to mitigate unwanted etching of and/or damage to one or more portions of the semiconductor device 100, such as one or more portions of the third dielectric layer 1702, during the wet etchant dipping process. Other techniques for removing the portions 2108, 2110, and 2112 are within the scope of the present disclosure, such as at least one of photolithography, chemical mechanical planarization (CMP), a washing process, stripping, or other suitable techniques.

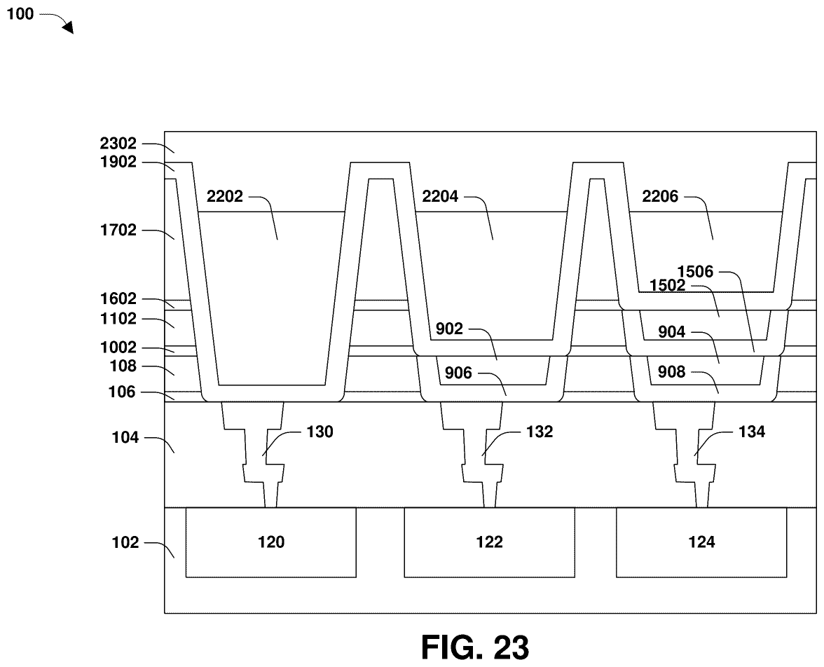

FIG. 23 illustrates an electroluminescence layer 2302 formed over the set of optical resonation structures, according to some embodiments. The electroluminescence layer 2302 is formed by at least one of PVD, sputtering, CVD, PECVD, LPCVD, ALCVD, UHVCVD, RPCVD, ALD, MBE, LPE, spin on, growth, or other suitable techniques. The electroluminescence layer 2302 at least one of (i) overlies one, some, or all optical resonation structures of the set of optical resonation structures, (ii) is in direct contact with one, some, or all optical resonation structures of the set of optical resonation structures, or (iii) is in indirect contact with one, some, or all optical resonation structures of the set of optical resonation structures. In some embodiments, the electroluminescence layer 2302 comprises an organic compound that emits light in response to an electric current. Other materials of the electroluminescence layer 2302 are within the scope of the present disclosure.

FIGS. 24A-24D illustrate patterning the electroluminescence layer 2302 to form a set of electroluminescence structures comprising at least one of a first electroluminescence structure 2402 comprising a first portion of the electroluminescence layer 2302, (ii) a second electroluminescence structure 2404 comprising a second portion of the electroluminescence layer 2302, or (iii) a third electroluminescence structure 2406 comprising a third portion of the electroluminescence layer 2302, according to some embodiments. Even though three electroluminescence structures of the set of electroluminescence structures are depicted, any number of electroluminescence structures of the set of electroluminescence structures are contemplated. A thickness 2430 (shown in FIG. 24A and FIG. 25A) of each electroluminescence structure of one, some or all of the set of electroluminescence structures is between about 10 angstroms to about 500,000 angstroms. Other values of the thickness 2430 are within the scope of the present disclosure.

In some embodiments, the electroluminescence layer 2302 is patterned to form the set of electroluminescence structures by a planarization process comprising at least one of CMP or other suitable techniques. In some embodiments, the planarization process comprises removing one or more top portions of at least one of the electroluminescence layer 2302 or the reflective layer 1902. In some embodiments, the planarization process is performed such that some or all of top surfaces 2408, 2410, and/or 2412 (of the first electroluminescence structure 2402, the second electroluminescence structure 2404, and/or the third electroluminescence structure 2406, respectively) are coplanar with each other. In some embodiments, performing the planarization process forms a set of reflective structures comprising at least one of a first reflective structure 2414 comprising a first portion of the reflective layer 1902, (ii) a second reflective structure 2416 comprising a second portion of the reflective layer 1902, or (iii) a third reflective structure 2418 comprising a third portion of the reflective layer 1902, according to some embodiments. Even though three reflective structures of the set of reflective structures are depicted, any number of reflective structures of the set of reflective structures are contemplated. Other processes and/or techniques for forming the set of electroluminescence structures and/or the set of reflective structures are within the scope of the present disclosure.

In some embodiments, the first reflective structure 2414 comprises at least one of (i) a first reflective base 2414a (shown with a dash line outline in FIG. 24A) underlying the first optical resonation structure 2202, (ii) a first reflective wall 2414b (shown with a dash-dash-dot line outline in FIG. 24A) aligned with a first side of the first optical resonation structure 2202, or a second reflective wall 2414c (shown with a dash-dash-dot line outline in FIG. 24A) aligned with a second side of the first optical resonation structure 2202 opposing the first side of the first optical resonation structure 2202. In some embodiments, at least one of the first reflective base 2414a, the first reflective wall 2414b, or the second reflective wall 2414c at least one of (i) is aligned with the first optical resonation structure 2202, (ii) is in direct contact with the first optical resonation structure 2202, or (iii) is in indirect contact with the first optical resonation structure 2202.

In some embodiments, the second reflective structure 2416 comprises at least one of (i) a second reflective base 2416a (shown with a dash line outline in FIG. 24A) underlying the second optical resonation structure 2204, (ii) a third reflective wall 2416b (shown with a dash-dash-dot line outline in FIG. 24A) aligned with a first side of the second optical resonation structure 2204, or a fourth reflective wall 2416c (shown with a dash-dash-dot line outline in FIG. 24A) aligned with a second side of the second optical resonation structure 2204 opposing the first side of the second optical resonation structure 2204. In some embodiments, at least one of the second reflective base 2416a, the third reflective wall 2416b, or the fourth reflective wall 2416c at least one of (i) is aligned with the second optical resonation structure 2204, (ii) is in direct contact with the second optical resonation structure 2204, or (iii) is in indirect contact with the second optical resonation structure 2204.

In some embodiments, the third reflective structure 2418 comprises at least one of (i) a third reflective base 2418a (shown with a dash line outline in FIG. 24A) underlying the third optical resonation structure 2206, (ii) a fifth reflective wall 2418b (shown with a dash-dash-dot line outline in FIG. 24A) aligned with a first side of the third optical resonation structure 2206, or a sixth reflective wall 2418c (shown with a dash-dash-dot line outline in FIG. 24A) aligned with a second side of the third optical resonation structure 2206 opposing the first side of the third optical resonation structure 2206. In some embodiments, at least one of the third reflective base 2418a, the fifth reflective wall 2418b, or the sixth reflective wall 2418c at least one of (i) is aligned with the third optical resonation structure 2206, (ii) is in direct contact with the third optical resonation structure 2206, or (iii) is in indirect contact with the third optical resonation structure 2206.

In some embodiments, some or all electroluminescence structures of the set of electroluminescence structures are coplanar such that a plane (e.g., a single plane comprising a horizontal line x1 shown in FIG. 24A) passes through and/or intersects with some or all the electroluminescence structures. In some embodiments, electroluminescence structures of the set of electroluminescence structures have different elevations (e.g., slightly different elevations), and the set of electroluminescence structures are coplanar such that a plane passes through and/or intersect with electroluminescence structures of the set of electroluminescence structures (even though top surfaces and/or bottom surfaces of the electroluminescence structures may not be coplanar).

In some embodiments, the semiconductor device 100 comprises a set of OLED cells comprising at least one of a first OLED cell 2424, a second OLED cell 2426, or a third OLED cell 2428. Even though three OLED cells of the set of OLED cells are depicted, any number of OLED cells of the set of OLED cells are contemplated. In some embodiments, the first OLED cell 2424 comprises at least one of (i) the first reflective structure 2414, (ii) the first electroluminescence structure 2402, or (iii) the first optical resonation structure 2202 between the first reflective base 2414a of the first reflective structure 2414 and the first electroluminescence structure 2402. In some embodiments, the second OLED cell 2426 comprises at least one of (i) the second reflective structure 2416, (ii) the second electroluminescence structure 2404, or (iii) the second optical resonation structure 2204 between the second reflective base 2416a of the second reflective structure 2416 and the second electroluminescence structure 2404. In some embodiments, the third OLED cell 2428 comprises at least one of (i) the third reflective structure 2418, (ii) the third electroluminescence structure 2406, or (iii) the third optical resonation structure 2206 between the third reflective base 2418a of the third reflective structure 2418 and the third electroluminescence structure 2406.

FIG. 24B illustrates a top view of the semiconductor device 100 in a first scenario, in accordance with some embodiments. In the first scenario, at least one of (i) electroluminescence structures of the set of electroluminescence structures have circular shapes, or (ii) reflective structures of the set of reflective structures have circular shapes. FIG. 24C illustrates a top view of the semiconductor device 100 in a second scenario, in accordance with some embodiments. In the second scenario, at least one of (i) electroluminescence structures of the set of electroluminescence structures have rectangular shapes, or (ii) reflective structures of the set of reflective structures have rectangular shapes. FIG. 24D illustrates a top view of the semiconductor device 100 in a third scenario, in accordance with some embodiments. In the third scenario, at least one of (i) electroluminescence structures of the set of electroluminescence structures have triangular shapes, or (ii) reflective structures of the set of reflective structures have triangular shapes. Other shapes of the set of electroluminescence structures and/or the set of reflective structures other than those shown and/or described herein are within the scope of the present disclosure.

FIGS. 25A-25D illustrate the semiconductor device 100 in a scenario in which the set of reflective structures comprises multi-layer structures, according to some embodiments. In some embodiments, the first reflective structure 2414 comprises a mirror structure M1 and a barrier structure B1, wherein the mirror structure M1 separates the barrier structure B1 from at least one of the first optical resonation structure 2202 or the first electroluminescence structure 2402. Thus, in accordance with some embodiments, (i) the first reflective base 2414a comprises a portion of the barrier structure B1 and a portion of the mirror structure M1, (ii) the first reflective wall 2414b comprises a portion of the barrier structure B1 and a portion of the mirror structure M1, and (iii) the second reflective wall 2414c comprises a portion of the barrier structure B1 and a portion of the mirror structure M1. In some embodiments, a thickness 2530 of the mirror structure M1 is greater than a thickness 2532 of the barrier structure B1. The thickness 2530 is between about 100 angstroms to about 500,000 angstroms. The thickness 2532 is between about 10 angstroms to about 100,000 angstroms. Other values of the thickness 2530 and the thickness 2532 are within the scope of the present disclosure.

In some embodiments, the second reflective structure 2416 comprises a mirror structure M2 and a barrier structure B2, wherein the mirror structure M2 separates the barrier structure B2 from at least one of the second optical resonation structure 2204 or the second electroluminescence structure 2404. Thus, in accordance with some embodiments, (i) the second reflective base 2416a comprises a portion of the barrier structure B2 and a portion of the mirror structure M2, (ii) the third reflective wall 2416b comprises a portion of the barrier structure B2 and a portion of the mirror structure M2, and (iii) the fourth reflective wall 2416c comprises a portion of the barrier structure B2 and a portion of the mirror structure M2. In some embodiments, a thickness 2534 of the mirror structure M2 is greater than a thickness 2536 of the barrier structure B2. The thickness 2534 is between about 100 angstroms to about 500,000 angstroms. The thickness 2536 is between about 10 angstroms to about 100,000 angstroms. Other values of the thickness 2534 and the thickness 2536 are within the scope of the present disclosure.

In some embodiments, the third reflective structure 2418 comprises a mirror structure M3 and a barrier structure B3, wherein the mirror structure M3 separates the barrier structure B3 from at least one of the third optical resonation structure 2206 or the third electroluminescence structure 2406. Thus, in accordance with some embodiments, (i) the third reflective base 2418a comprises a portion of the barrier structure B3 and a portion of the mirror structure M3, (ii) the fifth reflective wall 2418b comprises a portion of the barrier structure B3 and a portion of the mirror structure M3, and (iii) the sixth reflective wall 2418c comprises a portion of the barrier structure B3 and a portion of the mirror structure M3. In some embodiments, a thickness 2538 of the mirror structure M2 is greater than a thickness 2540 of the barrier structure B2. The thickness 2538 is between about 100 angstroms to about 500,000 angstroms. The thickness 2540 is between about 10 angstroms to about 100,000 angstroms. Other values of the thickness 2538 and the thickness 2540 are within the scope of the present disclosure.

In some embodiments, the reflective layer 1902 (shown in FIG. 19) comprises at least one of a first barrier layer or a first mirror layer. In some embodiments, forming the reflective layer 1902 comprises (i) forming the first barrier layer and (ii) forming the first mirror layer over the first barrier layer. At least one of the first barrier layer or the first mirror layer is formed by at least one of PVD, sputtering, CVD, PECVD, LPCVD, ALCVD, UHVCVD, RPCVD, ALD, MBE, LPE, spin on, growth, or other suitable techniques. In some embodiments, barrier structures B1, B2, and B3 comprise respective portions of the first barrier layer. In some embodiments, mirror structures M1, M2, and M3 comprise respective portions of the first mirror layer.

The first mirror layer is different than the first barrier layer, such as having a different material composition, such that an interface is defined between the first mirror layer and the first barrier layer. In some embodiments, the first mirror layer does not have a material composition different than the first barrier layer. An interface is nevertheless defined between the first mirror layer and the first barrier layer because the first mirror layer and the first barrier layer are separate, different, etc. layers. In some embodiments, a reflectivity of the first mirror layer to visible light (e.g., light having a wavelength between about 350 nanometers to about 780 nanometers) is greater than a reflectivity of the first barrier layer to visible light. In some embodiments, the reflectivity of the first mirror layer to visible light is at least about 80%. In some embodiments, the first mirror layer comprises a metal alloy and the first barrier layer comprises a metal alloy. In some embodiments, the first mirror layer (and mirror structures M1, M2, and M3 formed from the first mirror layer) comprises at least one of tungsten (W), copper (Cu), aluminum (Al), aluminum-copper (AlCu), aluminum-silicon-copper (AlSiCu), or other suitable material. In some embodiments, the first barrier layer (and barrier structures B1, B2, and B3 formed from the first barrier layer) comprises at least one of titanium nitride (TiN), tantalum nitride (TaN), tungsten (W), titanium (Ti), tantalum (Ta), or other suitable material. In some embodiments, the first barrier layer provides for improved adhesion of the reflective layer 1902 (and/or the first mirror layer) to sidewalls S1, S2, S3, S4, S5, S6, S7, S8, S9, S10, S11, S12, S13, S14, S15, S16, S17, S18, S19, S20, S21, S22, S23, and/or S24 (shown in FIG. 18). In some embodiments, the first barrier layer comprises an adhesive material.

In some embodiments, a concentration of carbon per unit of volume in the first mirror layer is different than a concentration of carbon per unit of volume in the first barrier layer. In some embodiments, a concentration of copper per unit of volume in the first mirror layer is different than a concentration of copper per unit of volume in the first barrier layer. In some embodiments, a concentration of aluminum per unit of volume in the first mirror layer is different than a concentration of aluminum per unit of volume in the first barrier layer. In some embodiments, a concentration of silicon per unit of volume in the first mirror layer is different than a concentration of silicon per unit of volume in the first barrier layer.

In some embodiments, the first conductive structure 906 comprises a mirror structure M4 and a barrier structure B4. In some embodiments, the second conductive structure 908 comprises a mirror structure M5 and a barrier structure B5. In some embodiments, the layer 702 (shown in FIG. 7) comprises at least one of a second barrier layer or a second mirror layer. In some embodiments, forming the layer 702 comprises (i) forming the second barrier layer and (ii) forming the second mirror layer over the second barrier layer. At least one of the second barrier layer or the second mirror layer is formed by at least one of PVD, sputtering, CVD, PECVD, LPCVD, ALCVD, UHVCVD, RPCVD, ALD, MBE, LPE, spin on, growth, or other suitable techniques. In some embodiments, barrier structures B4 and B5 comprise respective portions of the second barrier layer. In some embodiments, mirror structures M4 and M5 comprise respective portions of the second mirror layer. In some embodiments, a thickness 2542 of the mirror structure M4 is greater than a thickness 2544 of the barrier structure B4. The thickness 2542 is between about 100 angstroms to about 500,000 angstroms. The thickness 2544 is between about 10 angstroms to about 100,000 angstroms. In some embodiments, a thickness 2546 of the mirror structure M5 is greater than a thickness 2548 of the barrier structure B5. The thickness 2546 is between about 100 angstroms to about 500,000 angstroms. The thickness 2548 is between about 10 angstroms to about 100,000 angstroms. Other values of the thickness 2542, the thickness 2544, the thickness 2546, and the thickness 2548 are within the scope of the present disclosure.

The second mirror layer is different than the second barrier layer, such as having a different material composition, such that an interface is defined between the second mirror layer and the second barrier layer. In some embodiments, the second mirror layer does not have a material composition different than the second barrier layer. An interface is nevertheless defined between the second mirror layer and the second barrier layer because the second mirror layer and the second barrier layer are separate, different, etc. layers. In some embodiments, a reflectivity of the second mirror layer to visible light is greater than a reflectivity of the second barrier layer to visible light. In some embodiments, the reflectivity of the second mirror layer to visible light is at least about 80%. In some embodiments, the second mirror layer comprises a metal alloy and the second barrier layer comprises a metal alloy. In some embodiments, the second mirror layer (and mirror structures M4 and M5 formed from the second mirror layer) comprises at least one of tungsten (W), copper (Cu), aluminum (Al), aluminum-copper (AlCu), aluminum-silicon-copper (AlSiCu), or other suitable material. In some embodiments, the second barrier layer (and barrier structures B4 and B4 formed from the second barrier layer) comprises at least one of titanium nitride (TiN), tantalum nitride (TaN), tungsten (W), titanium (Ti), tantalum (Ta), or other suitable material. In some embodiments, the second barrier layer comprises an adhesive material.

In some embodiments, a concentration of carbon per unit of volume in the second mirror layer is different than a concentration of carbon per unit of volume in the second barrier layer. In some embodiments, a concentration of copper per unit of volume in the second mirror layer is different than a concentration of copper per unit of volume in the second barrier layer. In some embodiments, a concentration of aluminum per unit of volume in the second mirror layer is different than a concentration of aluminum per unit of volume in the second barrier layer. In some embodiments, a concentration of silicon per unit of volume in the second mirror layer is different than a concentration of silicon per unit of volume in the second barrier layer.

In some embodiments, the third conductive structure 1506 comprises a mirror structure M6 and a barrier structure B6. In some embodiments, the layer 1302 (shown in FIG. 13) comprises at least one of a third barrier layer or a third mirror layer. In some embodiments, forming the layer 1302 comprises (i) forming the third barrier layer and (ii) forming the third mirror layer over the third barrier layer. At least one of the third barrier layer or the third mirror layer is formed by at least one of PVD, sputtering, CVD, PECVD, LPCVD, ALCVD, UHVCVD, RPCVD, ALD, MBE, LPE, spin on, growth, or other suitable techniques. In some embodiments, the barrier structure B6 comprises a portion of the third barrier layer. In some embodiments, the mirror structure M6 comprises a portion of the third mirror layer.

In some embodiments, a thickness 2550 of the mirror structure M6 is greater than a thickness 2552 of the barrier structure B6. The thickness 2550 is between about 100 angstroms to about 500,000 angstroms. The thickness 2552 is between about 10 angstroms to about 100,000 angstroms. Other values of the thickness 2550 and the thickness 2552 are within the scope of the present disclosure.

The third mirror layer is different than the third barrier layer, such as having a different material composition, such that an interface is defined between the third mirror layer and the third barrier layer. In some embodiments, the third mirror layer does not have a material composition different than the third barrier layer. An interface is nevertheless defined between the third mirror layer and the third barrier layer because the third mirror layer and the third barrier layer are separate, different, etc. layers. In some embodiments, a reflectivity of the third mirror layer to visible light is greater than a reflectivity of the third barrier layer to visible light. In some embodiments, the reflectivity of the third mirror layer to visible light is at least about 80%. In some embodiments, the third mirror layer comprises a metal alloy and the third barrier layer comprises a metal alloy. In some embodiments, the third mirror layer (and the mirror structure M6 formed from the third mirror layer) comprises at least one of tungsten (W), copper (Cu), aluminum (Al), aluminum-copper (AlCu), aluminum-silicon-copper (AlSiCu), or other suitable material. In some embodiments, the third barrier layer (and the barrier structure B6 formed from the third barrier layer) comprises at least one of titanium nitride (TiN), tantalum nitride (TaN), tungsten (W), titanium (Ti), tantalum (Ta), or other suitable material. In some embodiments, the third barrier layer comprises an adhesive material.

In some embodiments, a concentration of carbon per unit of volume in the third mirror layer is different than a concentration of carbon per unit of volume in the third barrier layer. In some embodiments, a concentration of copper per unit of volume in the third mirror layer is different than a concentration of copper per unit of volume in the third barrier layer. In some embodiments, a concentration of aluminum per unit of volume in the third mirror layer is different than a concentration of aluminum per unit of volume in the third barrier layer. In some embodiments, a concentration of silicon per unit of volume in the third mirror layer is different than a concentration of silicon per unit of volume in the third barrier layer.

FIG. 25B illustrates a top view of the semiconductor device 100 in a scenario in which at least one of (i) electroluminescence structures of the set of electroluminescence structures have circular shapes, or (ii) reflective structures of the set of reflective structures have circular shapes, in accordance with some embodiments. FIG. 25C illustrates a top view of the semiconductor device 100 in a scenario in which at least one of (i) electroluminescence structures of the set of electroluminescence structures have rectangular shapes, or (ii) reflective structures of the set of reflective structures have rectangular shapes, in accordance with some embodiments. FIG. 25D illustrates a top view of the semiconductor device 100 in a scenario in which at least one of (i) electroluminescence structures of the set of electroluminescence structures have triangular shapes, or (ii) reflective structures of the set of reflective structures have triangular shapes, in accordance with some embodiments. Other shapes of the set of electroluminescence structures and/or the set of reflective structures other than those shown and/or described herein are within the scope of the present disclosure.

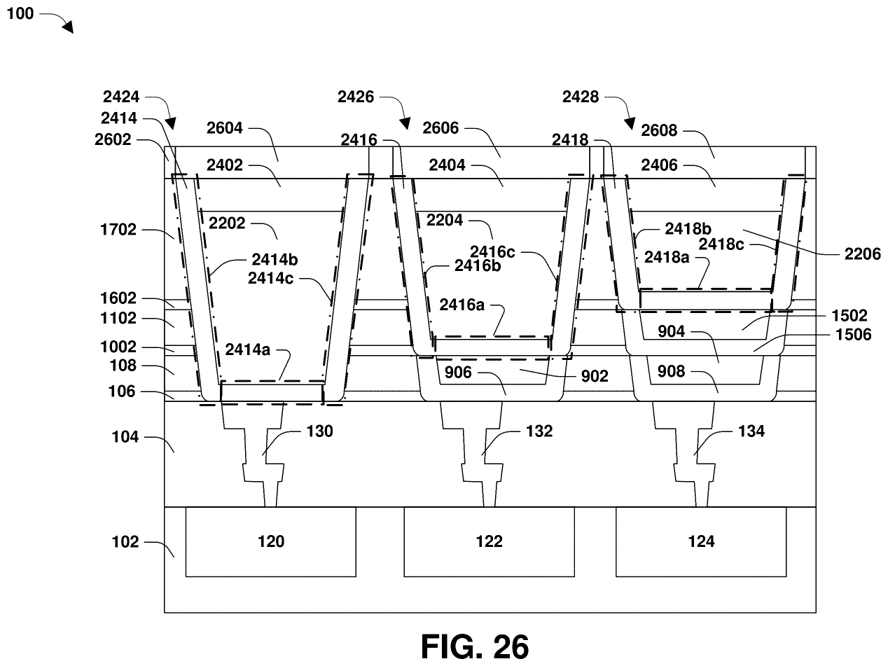

FIG. 26 illustrates forming a color filter layer 2602 over the set of electroluminescence structures and/or the set of reflective structures, according to some embodiments. The color filter layer 2602 is formed by at least one of PVD, sputtering, CVD, PECVD, LPCVD, ALCVD, UHVCVD, RPCVD, ALD, MBE, LPE, spin on, growth, or other suitable techniques. In some embodiments, the color filter layer 2602 comprises a set of color filters comprising at least one of a first color filter 2604 overlying the first electroluminescence structure 2402, a second color filter 2606 overlying the second electroluminescence structure 2404, or a third color filter 2608 overlying the third electroluminescence structure 2406. Even though three color filters of the set of color filters are depicted, any number of color filters of the set of color filters are contemplated.

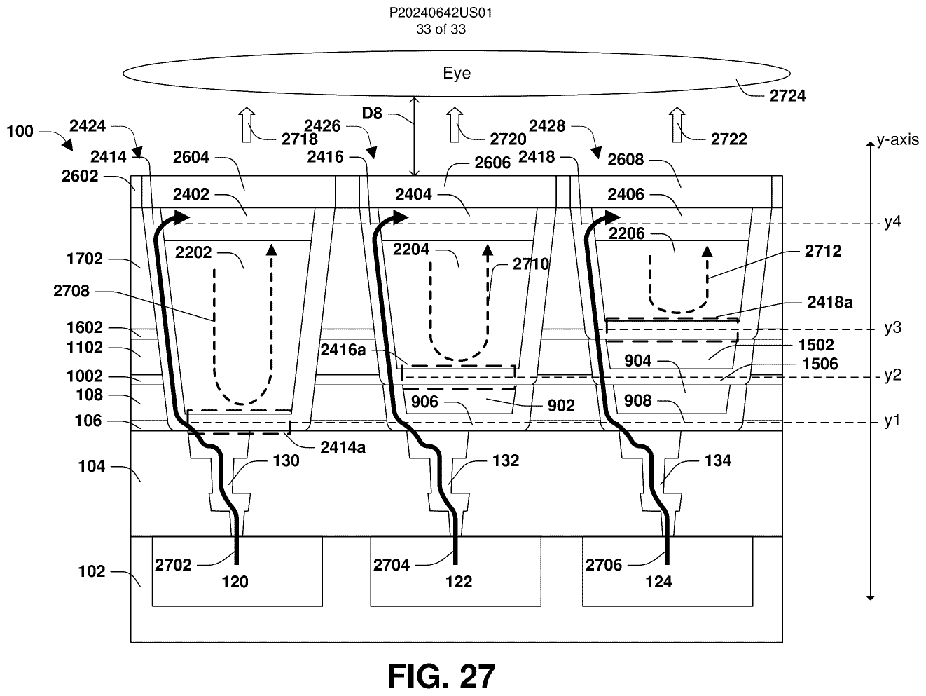

FIG. 27 illustrates aspects of operation of the semiconductor device 100, according to some embodiments. In some embodiments, the first interconnection component 130 is configured to establish a first electrical connection between the first OLED cell 2424 and the first OLED-cell driving circuitry 120. In some embodiments, the first OLED-cell driving circuitry 120 drives the first OLED cell 2424 via the first electrical connection. In some embodiments, the first OLED-cell driving circuitry 120 supplies a first electrical current 2702 to the first electroluminescence structure 2402 via the first electrical connection. In some embodiments, the first electrical current 2702 flows through at least one of the first interconnection component 130 or the first reflective structure 2414 (e.g., at least one of the mirror structure M1 or the barrier structure B1) to the first electroluminescence structure 2402. In some embodiments, the first electroluminescence structure 2402 is configured to emit first light, such as white light, in response to the first electrical current 2702. In some embodiments, the first electroluminescence structure 2402 emits the first light towards the first optical resonation structure 2202. In some embodiments, the first optical resonation structure 2202 comprises a first transparent material (e.g., at least one of an oxide semiconductor material, such as silicon oxide, a nitride semiconductor material, such as silicon nitride, undoped silicate glass (USG), phosphosilicate glass (PSG), fluorosilicate glass (FSG), a low-k dielectric material, an extreme low-k dielectric material, black diamond, or other suitable material) to establish a first light path 2708 between the first reflective base 2414a and the first electroluminescence structure 2402. In some embodiments, the first transparent material is transparent to visible light. In some embodiments, the first light travels along the first light path 2708. In some embodiments, at least some of the first light emitted from the first electroluminescence structure 2402 travels towards the first reflective base 2414a and is reflected by the first reflective base 2414a back towards at least one of the first electroluminescence structure 2402 or the first color filter 2604. At least some of the first light (e.g., reflected by the first reflective base 2414a) travels through at least one of the first electroluminescence structure 2402 or the first color filter 2604 to produce first emitted light 2718 emitted by the semiconductor device 100.

In some embodiments, the first OLED cell 2424 is associated with a first color. In some embodiments, a distance D1 (shown in FIG. 24A) between the first reflective base 2414a and the first electroluminescence structure 2402 is based upon the first color. In some embodiments, the first optical resonation structure 2202 is configured to provide first interference to the first light (traveling along the first light path 2708, for example) to at least one of (i) process the first light to produce a second light or (ii) extract the second light from the first light. In some embodiments, the second light comprises light having the first color. In some embodiments, an amount of light having the first color in the second light is greater than an amount of light having the first color in the first light, such as due, at least in part, to the first interference provided by the first optical resonation structure 2202 to the first light. In some embodiments, the second light travels through the first color filter 2604. In some embodiments, the first color filter 2604 filters the second light to produce the first emitted light 2718. In some embodiments, the first color filter 2604 filters, from the second light, wavelengths outside of a range of wavelengths associated with the first color to produce the first emitted light 2718. In some embodiments, an amount of the first interference depends upon the distance D1, and the distance D1 is controlled such that at least one of the first light, the second light, or the first emitted light 2718 has one or more desired colors (e.g., the first color). In some embodiments, the first color is red or other suitable color.

In some embodiments, the second interconnection component 132 is configured to establish a second electrical connection between the second OLED cell 2426 and the second OLED-cell driving circuitry 122. In some embodiments, the second OLED-cell driving circuitry 122 drives the second OLED cell 2426 via the second electrical connection. In some embodiments, the second OLED-cell driving circuitry 122 supplies a second electrical current 2704 to the second electroluminescence structure 2404 via the second electrical connection. In some embodiments, the second electrical current 2704 flows through at least one of the second interconnection component 132, the first conductive structure 906 (e.g., at least one of the mirror structure M4 or the barrier structure B4), or the second reflective structure 2416 (e.g., at least one of the mirror structure M2 or the barrier structure B2). In some embodiments, the second electrical current 2704 flows through a conductive material of the first filler structure 902. Embodiments are contemplated in which the first filler structure 902 comprises a non-conductive material or low-conductive material. In some embodiments, the second electroluminescence structure 2404 is configured to emit third light, such as white light, in response to the second electrical current 2704. In some embodiments, the second electroluminescence structure 2404 emits the third light towards the second optical resonation structure 2204. In some embodiments, the second optical resonation structure 2204 comprises a second transparent material (e.g., at least one of an oxide semiconductor material, such as silicon oxide, a nitride semiconductor material, such as silicon nitride, undoped silicate glass (USG), phosphosilicate glass (PSG), fluorosilicate glass (FSG), a low-k dielectric material, an extreme low-k dielectric material, black diamond, or other suitable material) to establish a second light path 2710 between the second reflective base 2416a and the second electroluminescence structure 2404. In some embodiments, the second transparent material is transparent to visible light. In some embodiments, the third light travels along the second light path 2710. In some embodiments, at least some of the third light emitted from the second electroluminescence structure 2404 travels towards the second reflective base 2416a and is reflected by the second reflective base 2416a back towards at least one of the second electroluminescence structure 2404 or the second color filter 2606. At least some of the third light (e.g., reflected by the second reflective base 2416a) travels through at least one of the second electroluminescence structure 2404 or the second color filter 2606 to produce second emitted light 2720 emitted by the semiconductor device 100.

In some embodiments, the second OLED cell 2426 is associated with a second color. In some embodiments, a distance D2 (shown in FIG. 24A) between the second reflective base 2416a and the second electroluminescence structure 2404 is based upon the second color. In some embodiments, the distance D2 is less than the distance D1 (shown in FIG. 24A) associated with the first OLED cell 2424. In some embodiments, the second optical resonation structure 2204 is configured to provide second interference to the third light (traveling along the second light path 2710, for example) to at least one of (i) process the third light to produce a fourth light or (ii) extract the fourth light from the third light. In some embodiments, the fourth light comprises light having the second color. In some embodiments, an amount of light having the second color in the fourth light is greater than an amount of light having the second color in the third light, such as due, at least in part, to the second interference provided by the second optical resonation structure 2204 to the third light. In some embodiments, the fourth light travels through the second color filter 2606. In some embodiments, the second color filter 2606 filters the fourth light to produce the second emitted light 2720. In some embodiments, the second color filter 2606 filters, from the fourth light, wavelengths outside of a range of wavelengths associated with the second color to produce the second emitted light 2720. In some embodiments, an amount of the second interference depends upon the distance D2, and the distance D2 is controlled such that at least one of the third light, the fourth light, or the second emitted light 2720 has one or more desired colors (e.g., the second color). In some embodiments, the second color is green or other suitable color.

In some embodiments, the third interconnection component 134 is configured to establish a third electrical connection between the third OLED cell 2428 and the third OLED-cell driving circuitry 124. In some embodiments, the third OLED-cell driving circuitry 124 drives the third OLED cell 2428 via the third electrical connection. In some embodiments, the third OLED-cell driving circuitry 124 supplies a third electrical current 2706 to the third electroluminescence structure 2406 via the third electrical connection. In some embodiments, the third electrical current 2706 flows through at least one of the third interconnection component 134, the second conductive structure 908 (e.g., at least one of the mirror structure M5 or the barrier structure B5), the third conductive structure 1506 (e.g., at least one of the mirror structure M6 or the barrier structure B6), or the third reflective structure 2418 (e.g., at least one of the mirror structure M3 or the barrier structure B3). In some embodiments, the third electrical current 2706 flows through at least one of a conductive material of the second filler structure 904 or a conductive material of the third filler structure 1502. Embodiments are contemplated in which at least one of the second filler structure 904 comprises a non-conductive material or low-conductive material or the third filler structure 1502 comprises a non-conductive material or low-conductive material. In some embodiments, the third electroluminescence structure 2406 is configured to emit fifth light, such as white light, in response to the third electrical current 2706. In some embodiments, the third electroluminescence structure 2406 emits the fifth light towards the third optical resonation structure 2206. In some embodiments, the third optical resonation structure 2206 comprises a third transparent material (e.g., at least one of an oxide semiconductor material, such as silicon oxide, a nitride semiconductor material, such as silicon nitride, undoped silicate glass (USG), phosphosilicate glass (PSG), fluorosilicate glass (FSG), a low-k dielectric material, an extreme low-k dielectric material, black diamond, or other suitable material) to establish a third light path 2712 between the third reflective base 2418a and the third electroluminescence structure 2406. In some embodiments, the third transparent material is transparent to visible light. In some embodiments, the fifth light travels along the third light path 2712. In some embodiments, at least some of the fifth light emitted from the third electroluminescence structure 2406 travels towards the third reflective base 2418a and is reflected by the third reflective base 2418a back towards at least one of the third electroluminescence structure 2406 or the third color filter 2608. At least some of the fifth light (e.g., reflected by the third reflective base 2418a) travels through at least one of the third electroluminescence structure 2406 or the third color filter 2608 to produce third emitted light 2722 emitted by the semiconductor device 100.

In some embodiments, the third OLED cell 2428 is associated with a third color. In some embodiments, a distance D3 (shown in FIG. 24A) between the third reflective base 2418a and the third electroluminescence structure 2406 is based upon the third color. In some embodiments, the distance D3 is less than at least one of (i) the distance D1 (shown in FIG. 24A) associated with the first OLED cell 2424 or (ii) the distance D2 (shown in FIG. 24A) associated with the second OLED cell 2426. In some embodiments, the third optical resonation structure 2206 is configured to provide third interference to the fifth light (traveling along the third light path 2712, for example) to at least one of (i) process the fifth light to produce a sixth light or (ii) extract the sixth light from the fifth light. In some embodiments, the sixth light comprises light having the third color. In some embodiments, an amount of light having the third color in the sixth light is greater than an amount of light having the third color in the fifth light, such as due, at least in part, to the third interference provided by the third optical resonation structure 2206 to the fifth light. In some embodiments, the sixth light travels through the third color filter 2608. In some embodiments, the third color filter 2608 filters the sixth light to produce the third emitted light 2722. In some embodiments, the third color filter 2608 filters, from the sixth light, wavelengths outside of a range of wavelengths associated with the third color to produce the third emitted light 2722. In some embodiments, an amount of the third interference depends upon the distance D3, and the distance D3 is controlled such that at least one of the fifth light, the sixth light, or the third emitted light 2722 has one or more desired colors (e.g., the third color). In some embodiments, the third color is blue or other suitable color.

In some embodiments, the semiconductor device 100 comprises a near eye display (NED), such as an OLED near eye display panel. In some embodiments, a distance D7 (shown in FIG. 27) between the semiconductor device 100 and a user's eye is less than a first threshold distance associated with near eye display technology. In some embodiments, the semiconductor device 100 is part of a wearable device, such as a headset, that is worn by the user such that the semiconductor device 100 is positioned facing the eye of the user. In some embodiments, the semiconductor device 100 provides at least one of an immersive experience, an augmented reality experience, a mixed reality experience, etc.

In some embodiments, an elevation y1 of the first reflective base 2414a is different than (e.g., lower than) an elevation y2 of the second reflective base 2416a. In some embodiments, an elevation difference between the elevation y1 of the first reflective base 2414a and the elevation y2 of the second reflective base 2416a is less than an elevation difference between an elevation (e.g., an elevation y4) of the first electroluminescence structure 2402 and an elevation (e.g., the elevation y4) of the second electroluminescence structure 2404. In some embodiments, the elevation y2 of the second reflective base 2416a is different than (e.g., lower than) an elevation y3 of the third reflective base 2418a. In some embodiments, an elevation difference between the elevation y2 of the second reflective base 2416a and the elevation y3 of the third reflective base 2418a is less than an elevation difference between the elevation (e.g., the elevation y4) of the second electroluminescence structure 2404 and an elevation (e.g., the elevation y4) of the third electroluminescence structure 2406.

In some embodiments, a first pixel of the semiconductor device 100 comprises at least one of the first OLED cell 2424 (e.g., a red sub-pixel), the second OLED cell 2426 (e.g., a green sub-pixel), or the third OLED cell 2428 (e.g., a blue sub-pixel). In some embodiments, the semiconductor device 100 comprises a plurality of pixels arranged in an array of pixels. In some embodiments, each pixel of some or all of the plurality of pixels comprises one or more OLED cells comprising at least one of an OLED cell configured to emit light having the first color (e.g., red), an OLED cell configured to emit light having the second color (e.g., green), or an OLED cell configured to emit light having the third color (e.g., blue), wherein the one or more OLED cells are formed using one or more of the techniques provided herein with respect to forming the first OLED cell 2424, the second OLED cell 2426, and/or the third OLED cell 2428. A pixel width D4 (shown in FIGS. 24A-24D and 25A-25D) of the first pixel is between about 10 micrometers to about 100 micrometers, such as about 50 micrometers. A pixel length D5 (shown in FIGS. 24B-24D and 25B-25D) of the first pixel is between about 10 micrometers to about 100 micrometers, such as about 50 micrometers. Other values of the pixel width D4 and the pixel length D5 are within the scope of the present disclosure.

In some embodiments, the semiconductor device 100 comprises a first set of OLED cells associated with the first color. In some embodiments, the first set of OLED cells comprise the first OLED cell 2424. In some embodiments, each of the first set of OLED cells is configured to emit light having the first color (e.g., red). In some embodiments, reflective bases (e.g., the first reflective base 2414a) of some or all OLED cells of the first set of OLED cells are coplanar.

In some embodiments, the semiconductor device 100 comprises a second set of OLED cells associated with the second color. In some embodiments, the second set of OLED cells comprise the second OLED cell 2426. In some embodiments, each of the second set of OLED cells is configured to emit light having the second color (e.g., green). In some embodiments, reflective bases (e.g., the second reflective base 2416a) of some or all OLED cells of the second set of OLED cells are coplanar.

In some embodiments, the semiconductor device 100 comprises a third set of OLED cells associated with the third color. In some embodiments, the third set of OLED cells comprise the third OLED cell 2428. In some embodiments, each of the third set of OLED cells is configured to emit light having the third color (e.g., blue). In some embodiments, reflective bases (e.g., the third reflective base 2418a) of some or all OLED cells of the third set of OLED cells are coplanar.

In some embodiments, the present disclosure provides for benefits including, but not limited to, at least one of (i) improved uniformity of thicknesses of electroluminescence structures, (ii) increased uniformity of light emitted by OLED cells and/or pixels of the semiconductor device 100, (iii) increased predictability of display performance of the semiconductor device 100, (iv) faster semiconductor device fabrication speed of fabricating the semiconductor device 100. In some embodiments, at least some of the benefits are due, at least in part, to at least one of (i) patterning the electroluminescence layer 2302 and/or performing the planarization process to produce the set of electroluminescence structures, (ii) electroluminescence structures of the set of electroluminescence structures being coplanar, etc.

In some embodiments, a semiconductor device is provided. The semiconductor device includes a first OLED cell and a second OLED cell. The first OLED cell includes a first reflective base, a first electroluminescence structure over the first reflective base, and a first optical resonation structure between the first electroluminescence structure and the first reflective base. The second OLED cell includes a second reflective base, a second electroluminescence structure over the second reflective base, and a second optical resonation structure between the second electroluminescence structure and the second reflective base, wherein an elevation of the first reflective base is different than an elevation of the second reflective base.

In some embodiments, a method of forming a semiconductor device is provided. The method includes forming one or more dielectric layers over an interconnection layer. The method includes forming a first trench and a second trench in the one or more dielectric layers. The method includes forming a first reflective base of a first OLED cell in the first trench. The method includes forming a second reflective base of a second OLED cell in the second trench. An elevation of the first reflective base is different than an elevation of the second reflective base.

In some embodiments, a semiconductor device is provided. The semiconductor device includes a first OLED cell configured to produce a light having a first color and a second OLED cell configured to produce a light having a second color different than the first color. The first OLED cell includes a first optical resonation structure and a first electroluminescence structure over the first optical resonation structure. The second OLED cell includes a second optical resonation structure and a second electroluminescence structure over the second optical resonation structure. The first electroluminescence structure is coplanar with the second electroluminescence structure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A semiconductor device, comprising:
a first organic light-emitting diode (OLED) cell comprising:
a first reflective base;
a first electroluminescence structure over the first reflective base; and
a first optical resonation structure between the first electroluminescence structure and the first reflective base; and
a second OLED cell comprising:
a second reflective base;
a second electroluminescence structure over the second reflective base; and
a second optical resonation structure between the second electroluminescence structure and the second reflective base, wherein an elevation of the first reflective base is different than an elevation of the second reflective base.

2. The semiconductor device of claim 1, wherein:
a difference between the elevation of the first reflective base and the elevation of the second reflective base is less than a difference between an elevation of the first electroluminescence structure and an elevation of the second electroluminescence structure.

3. The semiconductor device of claim 1, comprising:
a first interconnection component configured to establish an electrical connection between the first OLED cell and at least one of a first transistor or a first capacitor; and
a second interconnection component configured to establish an electrical connection between the second OLED cell and at least one of a second transistor or a second capacitor.

4. The semiconductor device of claim 1, wherein:
a distance between the first reflective base and the first electroluminescence structure is greater than a distance between the second reflective base and the second electroluminescence structure.

5. The semiconductor device of claim 1, wherein:
the first OLED cell is configured to produce a light having a first color; and
the second OLED cell is configured to produce a light having a second color different than the first color.

6. The semiconductor device of claim 5, wherein:
a distance between the first reflective base and the first electroluminescence structure is based upon the first color; and
a distance between the second reflective base and the second electroluminescence structure is based upon the second color.

7. The semiconductor device of claim 5, comprising
a third OLED cell configured to produce a light having a third color, the third OLED comprising:
a third reflective base;
a third electroluminescence structure over the third reflective base; and
a third optical resonation structure between the third electroluminescence structure and the third reflective base, wherein an elevation of the third reflective base is different than the elevation of the first reflective base and the elevation of the second reflective base.

8. The semiconductor device of claim 7, wherein at least one of:
the first color corresponds to red;
the second color corresponds to green; or
the third color corresponds to blue.

9. The semiconductor device of claim 7, wherein:
a distance between the third reflective base and the third electroluminescence structure is based upon the third color.

10. The semiconductor device of claim 1, wherein:
the first optical resonation structure comprises a first transparent material to establish a first light path between the first reflective base and the first electroluminescence structure; and
the second optical resonation structure comprises a second transparent material to establish a second light path between the second reflective base and the second electroluminescence structure.

11. A method of forming a semiconductor device, comprising:
forming one or more dielectric layers over an interconnection layer;
forming a first trench and a second trench in the one or more dielectric layers;
forming a first reflective base of a first organic light-emitting diode (OLED) cell in the first trench; and
forming a second reflective base of a second OLED cell in the second trench, wherein an elevation of the first reflective base is different than an elevation of the second reflective base.

12. The method of claim 11, wherein:
forming the first trench and the second trench comprises forming the first trench and the second trench such that an elevation of a first base of the first trench is different than an elevation of a second base of the second trench.

13. The method of claim 11, comprising:
forming, in the first trench, a first optical resonation structure of the first OLED cell over the first reflective base; and
forming, in the second trench, a second optical resonation structure of the second OLED cell over the second reflective base.

14. The method of claim 13, comprising:
forming an electroluminescence layer over the one or more dielectric layers; and
patterning the electroluminescence layer to:
form a first electroluminescence structure, of the first OLED cell, over the first optical resonation structure; and
form a second electroluminescence structure, of the second OLED cell, over the second optical resonation structure.

15. The method of claim 14, wherein:
patterning the electroluminescence layer comprises patterning the electroluminescence layer such that the first electroluminescence structure is coplanar with the second electroluminescence structure.

16. The method of claim 11, wherein:
forming the first trench comprises forming the first trench over a first interconnection component in the interconnection layer, wherein the first interconnection component is configured to establish an electrical connection between the first OLED cell and at least one of a first transistor or a first capacitor; and
forming the second trench comprises forming the second trench over a second interconnection component in the interconnection layer, wherein the second interconnection component is configured to establish an electrical connection between the second OLED cell and at least one of a second transistor or a second capacitor.

17. The method of claim 14, wherein:
patterning the electroluminescence layer comprises:
forming the first electroluminescence structure to be a first distance from the first reflective base, wherein the first distance is based upon a first color associated with the first OLED cell; and
forming the second electroluminescence structure to be a second distance from the second reflective base, wherein the second distance is based upon a second color associated with the second OLED cell.

18. The method of claim 11, comprising:
forming a third trench in the one or more dielectric layers; and
forming a third reflective base of a third OLED cell in the third trench, wherein the elevation of the second reflective base is different than an elevation of the third reflective base.

19. A semiconductor device, comprising:
a first organic light-emitting diode (OLED) cell configured to produce a light having a first color, the first OLED cell comprising:
a first optical resonation structure; and
a first electroluminescence structure over the first optical resonation structure; and
a second OLED cell configured to produce a light having a second color different than the first color, the second OLED cell comprising:
a second optical resonation structure; and
a second electroluminescence structure over the second optical resonation structure, wherein the first electroluminescence structure is coplanar with the second electroluminescence structure.

20. The semiconductor device of claim 19, wherein:
the first OLED cell comprises a first reflective base;
the second OLED cell comprises a second reflective base; and
an elevation of the first reflective base is different than an elevation of the second reflective base.
